(19) United States
(12) Patent Application Publication
(10) Pub. No.: US 2024/0030389 A1
(43) Pub. Date: Jan. 25, 2024

(54) DISPLAY DEVICE AND METHOD OF FABRICATING THE SAME

(71) Applicant: Samsung Display Co., LTD., Yongin-si (KR)

(72) Inventors: Tae Gyun KIM, Yongin-si (KR); Soo Chul KIM, Yongin-si (KR); Jin Taek PARK, Yongin-si (KR); Dae Ho SONG, Yongin-si (KR); So Young YEO, Yongin-si (KR); Ki Beom LEE, Yongin-si (KR); Eok Yi LEE, Yongin-si (KR); Seong Won CHO, Yongin-si (KR); Jae Ho CHOI, Yongin-si (KR)

(21) Appl. No.: 18/348,938

(22) Filed: Jul. 7, 2023

(30) Foreign Application Priority Data
Jul. 20, 2022 (KR) 10-2022-0089500

(51) Int. Cl. H01L 33/50; H01L 25/075; H01L 25/16; H01L 33/46; H01L 33/58

(52) U.S. Cl. CPC H01L 33/505; H01L 25/0753; H01L 25/167; H01L 33/46; H01L 33/58; H01L 2933/0041; H01L 2933/0025

(57) ABSTRACT

The present disclosure may provide a display device and method of fabricating the same. According to one or more embodiments, a display device includes a first substrate including pixel circuit units, a plurality of light-emitting elements on the first substrate, a partition wall filling gaps between the light-emitting elements and providing spaces in emission areas, on the light-emitting elements and wavelength conversion layers in the spaces.

### CROSS-REFERENCE TO RELATED APPLICATION

The present application claims priority to and the benefit of Korean Patent Application No. 10-2022-0089500 filed on Jul. 20, 2022, in the Korean Intellectual Property Office, the entire content of which is incorporated by reference herein.

### BACKGROUND

### 1. Field

The present disclosure relates to a display device and a method of fabricating the same.

### 2. Description of the Related Art

Display devices are becoming more important with developments in multimedia technology. Accordingly, various display devices such as an organic light-emitting diode (OLED) display device, a liquid crystal display (LCD) device, and the like have been used.

Typically, a display device includes a display panel such as an organic light-emitting display panel or an LCD panel. A light-emitting display panel may include light-emitting elements such as, for example, light-emitting diodes (LEDs). Examples of the LEDs include organic LEDs (OLEDs) using an organic material as a light-emitting material and inorganic LEDs using an inorganic material as a light-emitting material.

### SUMMARY

Aspects and features of embodiments of the present disclosure provide a display device and a method of fabricating the same, which can control the thickness and height of a partition wall by forming the partition wall of an organic insulating material and can improve the degree of freedom of design of a wavelength conversion layer by forming the wavelength conversion layer through the etching of the partition wall.

However, aspects and features of embodiments of the present disclosure are not limited to those set forth herein. The above and other aspects and features of the present disclosure will become more apparent to one of ordinary skill in the art to which the present disclosure pertains by referencing the detailed description of the present disclosure given below.

According to one or more embodiments of the present disclosure, a display device includes a first substrate including pixel circuit units, a plurality of light-emitting elements on the first substrate, a partition wall filling gaps between the light-emitting elements and forming spaces in emission areas, on the light-emitting elements and wavelength conversion layers in the spaces.

The partition wall includes an organic insulating material.

The display device further includes a plurality of pixel electrodes on the pixel circuit units and connecting electrodes between the pixel electrodes and the light-emitting elements.

The display device further includes a light-blocking member on the partition wall and color filters on the wavelength conversion layers.

The display device further includes lenses on the light-emitting elements in the spaces to condense light.

The display device further includes lenses on the color filters to condense light.

The display device further includes first reflective layers on sides of each of the light-emitting elements and second reflective layers on sides of each of the wavelength conversion layers.

First surfaces of the second reflective layers are in contact with the sides of each of the wavelength conversion layers, and second surfaces of the second reflective layers are in contact with the partition wall.

The wavelength conversion layers are longer than the light-emitting elements in a vertical direction perpendicular to a thickness direction, and the display device further includes third reflective layers at bottoms of parts of the wavelength conversion layers, the third reflective layer not overlapping with the light-emitting elements.

The display device further includes a first insulating layer on parts of the first substrate where the pixel electrodes are not located and a second insulating layer on a top surface and sides of each of the light-emitting elements, sides of each of the connecting electrodes, and parts of the first insulating layer where the light-emitting elements are located, wherein the second insulating layer includes openings on the top surfaces of the light-emitting elements.

The display device further includes a common electrode on the second insulating layer and electrically connected to the light-emitting elements through the openings, wherein a width of the partition wall between the light-emitting elements is less than or equal to a width of the light-emitting elements.

The light-emitting elements include first, second, and third light-emitting elements configured to emit first light, second light, and third light, respectively, and the wavelength conversion layers include a base resin and a scatterer configured to scatter light.

The light-emitting elements include first, second, and third light-emitting elements configured to emit first light, second light, and third light, respectively, and are located in first, second, and third emission areas, respectively and the wavelength conversion layers include a light-transmitting pattern in the first emission area and includes a first base resin and a first scatterer configured to scatter light, a first wavelength conversion pattern in the second emission area and includes a second base resin, a second scatterer configured to scatter light, and first wavelength conversion particles configured to convert the first light to second light, and a second wavelength conversion pattern in the third emission area and including a third base resin, a third scatterer configured to scatter light, and second wavelength conversion particles configured to convert the first light to third light.

Each of the light-emitting elements includes a first semiconductor layer, an active layer on the first semiconductor layer, and a second semiconductor layer on the active layer.

According to the aforementioned and other embodiments of the present disclosure, a method of fabricating a display device includes bonding a first substrate including a pixel electrode layer, and a second substrate including a light-emitting material layer, fusion-bonding first connecting electrodes and second connecting electrodes and separating the second substrate from a light-emitting material layer, forming light-emitting elements by etching the light-emitting material layer, forming a partition wall and spaces for forming wavelength conversion layers, by applying an organic insulating material layer to cover the light-emitting elements and etching the organic insulating material layer on the light-emitting elements and forming the wavelength conversion layers in the spaces.

The bonding the first and second substrates, includes forming the first connecting electrodes and the second connecting electrodes on the first and second substrates, respectively, fusion-bonding the first connecting electrodes and the second connecting electrodes, and separating the second substrate from the light-emitting elements.

The method further includes after the forming the light-emitting elements, forming an insulating layer on a top surface and sides of each of the light-emitting elements, on sides of each of connecting electrodes, and on parts of the first substrate where the light-emitting elements are not located, forming openings, exposing parts of the top surfaces of the light-emitting elements, by etching parts of the insulating layer on the top surfaces of the light-emitting elements, and forming a common electrode on the openings and the insulating layer.

The method further comprises depositing reflective layers on the common electrode, removing parts of the reflective layers in first and second directions, with an etching material, by forming a large voltage difference in a third direction, and forming first reflective layers overlapping with sides of each of the light-emitting elements.

The method further includes before the forming the wavelength conversion layers, depositing reflective layers on the partition wall and the spaces, removing parts of the reflective layers in first and second directions, with an etching material, by forming a large voltage difference in a third direction, and forming second reflective layers overlapping with sides of each of the spaces.

The method further comprises forming a light-blocking member on the partition wall; and disposing color filters on the wavelength conversion layers.

It should be noted that the effects of the present disclosure are not limited to those described above, and other effects of the present disclosure will be apparent from the following description.

### BRIEF DESCRIPTION OF THE DRAWINGS

The above and other aspects and features of the present disclosure will become more apparent by describing in detail embodiments thereof with reference to the attached drawings, in which:

FIG. 1 is a plan view of a display device according to one or more embodiments of the present disclosure;

FIG. 2 is a layout view of the circuitry of a display substrate of the display device of FIG. 1;

FIG. 3 is an equivalent circuit diagram of a pixel of the display device of FIG. 1;

FIG. 4 is an equivalent circuit diagram of a pixel of a display device according to one or more embodiments of the present disclosure;

FIG. 5 is an equivalent circuit diagram of a pixel of a display device according to one or more embodiments of the present disclosure;

FIG. 6 is a layout view of an area A of FIG. 1;

FIG. 7 is a cross-sectional view taken along the line B-B′ of FIG. 6;

FIG. 8 is a cross-sectional view of a pixel electrode and a light-emitting element according to one or more embodiments of the present disclosure;

FIG. 9 is an enlarged cross-sectional view of the light-emitting element of FIG. 8;

FIG. 10 is a cross-sectional view of a display device according to one or more embodiments of the present disclosure;

FIG. 11 is a cross-sectional view of a display device according to one or more embodiments of the present disclosure;

FIG. 12 is a cross-sectional view of a display device according to one or more embodiments of the present disclosure;

FIG. 13 is a cross-sectional view of a display device according to one or more embodiments of the present disclosure;

FIG. 14 is a cross-sectional view of a display device according to one or more embodiments of the present disclosure;

FIG. 15 is a cross-sectional view of a display device according to one or more embodiments of the present disclosure;

FIGS. 16 through 27 are cross-sectional views illustrating a method of fabricating a display device according to one or more embodiments of the present disclosure; and

FIG. 28 is a flowchart illustrating the method of fabricating a display device according to one or more embodiments of the present disclosure.

FIG. 29 is an example diagram showing a virtual reality device including a display device according to one or more embodiments.

FIG. 30 is an example diagram showing a smart device including a display device according to one or more embodiments.

FIG. 31 is a diagram showing a vehicle including a display device according to one or more embodiments.

FIG. 32 is one example diagram showing a transparent display device including a display device according to one or more embodiments.

### DETAILED DESCRIPTION

The embodiments will now be described more fully hereinafter with reference to the accompanying drawings. The embodiments may, however, be provided in different forms and should not be construed as limiting. The same reference numbers indicate the same components throughout the present disclosure. In the accompanying figures, the thickness of layers and regions may be exaggerated for clarity.

Some of the parts that are not associated with the description may not be provided in order to describe embodiments of the present disclosure.

It will also be understood that when a layer is referred to as being “on” another layer or substrate, it can be directly on the other layer or substrate, or intervening layers may also be present. In contrast, when an element is referred to as being “directly on” another element, there may be no intervening elements present.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and vice versa. Additionally, the term “overlap” may include layer, stack, face or facing, extending over, covering, or partly covering or any other suitable term as would be appreciated and understood by those of ordinary skill in the art. The expression “not overlap” may include meaning such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

The spatially relative terms “below,” “beneath,” “lower,” “above,” “upper,” or the like, may be used herein for ease of description to describe the relations between one element or component and another element or component as illustrated in the drawings. It will be understood that the spatially relative terms are intended to encompass different orientations of the device in use or operation, in addition to the orientation depicted in the drawings. For example, in the case where a device illustrated in the drawing is turned over, the device positioned “below” or “beneath” another device may be placed “above” another device. Accordingly, the illustrative term “below” may include both the lower and upper positions. The device may also be oriented in other directions and thus the spatially relative terms may be interpreted differently depending on the orientations.

When an element is referred to as being “connected” or “coupled” to another element, the element may be “directly connected” or “directly coupled” to another element, or “electrically connected” or “electrically coupled” to another element with one or more intervening elements interposed therebetween. It will be further understood that when the terms “comprises,” “comprising,” “has,” “have,” “having,” “includes” and/or “including” are used, they may specify the presence of stated features, integers, steps, operations, elements and/or components, but do not preclude the presence or addition of other features, integers, steps, operations, elements, components, and/or any combination thereof.

It will be understood that, although the terms “first,” “second,” “third,” or the like may be used herein to describe various elements, these elements should not be limited by these terms. These terms are used to distinguish one element from another element or for the convenience of description and explanation thereof. For example, when “a first element” is discussed in the description, it may be termed “a second element” or “a third element,” and “a second element” and “a third element” may be termed in a similar manner without departing from the teachings herein.

The terms “about” or “approximately” as used herein is inclusive of the stated value and means within an acceptable range of deviation for the particular value as determined by one of ordinary skill in the art, considering the measurement in question and the error associated with measurement of the particular quantity (for example, the limitations of the measurement system). For example, “about” may mean within one or more standard deviations, or within ±30%, 20%, 10%, 5% of the stated value.

In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.” In the specification and the claims, the phrase “at least one of” is intended to include the meaning of “at least one selected from the group of” for the purpose of its meaning and interpretation. For example, “at least one of A and B” may be understood to mean “A, B, or A and B.”

Unless otherwise defined or implied, all terms used herein (including technical and scientific terms) have the same meaning as commonly understood by those skilled in the art to which the present disclosure pertains. It will be further understood that terms, such as those defined in commonly used dictionaries, should be interpreted as having a meaning that is consistent with their meaning in the context of the relevant art and will not be interpreted in an ideal or excessively formal sense unless clearly defined in the specification.

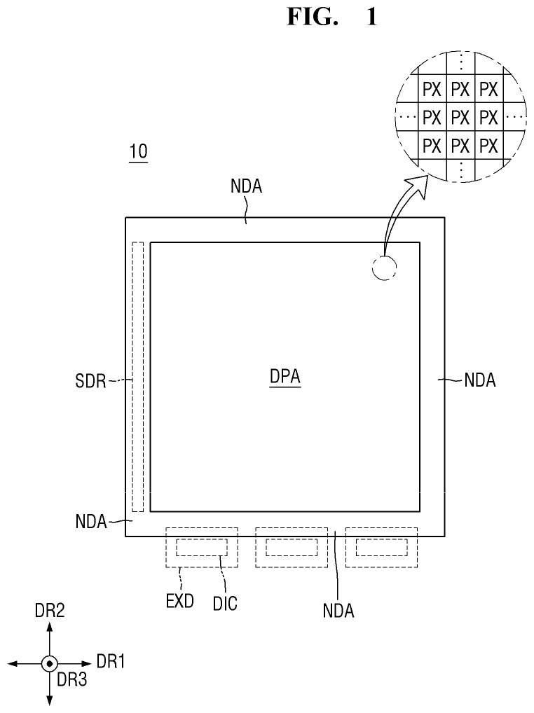

FIG. 1 is a plan view of a display device according to one or more embodiments of the present disclosure.

Referring to FIG. 1, a display device 10 may be applicable to smartphones, mobile phones, tablet personal computers (PCs), personal digital assistants (PDAs), portable multimedia players (PMPs), televisions (TVs), game consoles, wristwatch-type electronic devices, head-mounted displays, PC monitors, notebook computers, car navigation systems, car dashboards, digital cameras, camcorders, electric billboards, various medical devices, various inspection devices, home appliances (such as refrigerators and washing machines), and Internet-of-Things (IoT) devices. The display device 10 will hereinafter be described as being, for example, a TV having a high or ultrahigh resolution such as HD, UHD, 4K, or 8K.

The display device 10 may be classified according to how it displays an image. For example, the display device 10 may be an organic light-emitting diode (OLED) display device, an inorganic electro-luminescence (EL) display device, a quantum-dot light-emitting display (QED) device, a micro-light-emitting diode (micro-LED) display device, a nano-light-emitting diode (nano-LED) display device, a plasma display device (PDP), a field emission display (FED) device, a cathode-ray tube (CRT) device, a liquid crystal display (LCD) device, or an electrophoretic display (EPD) device. The display device 10 will hereinafter be described as being, for example, an OLED display device, and an OLED display device will hereinafter be simply referred to as a display device, unless specified otherwise. However, the display device 10 is not limited to an OLED display device, and various other display devices may also be applicable to the display device 10.

A first direction DR1 refers to the horizontal direction of the display device 10, a second direction DR2 refers to the vertical direction of the display device 10, and a third direction DR3 refers to the thickness direction of the display device 10. The terms “left,” “right,” “upper,” and “lower,” as used herein, refer to their respective directions as viewed from above the display device 10. For example, the term “right side” refers to one side in the first direction DR1, the term “left side” refers to the other side in the first direction DR1, the term “upper side” refers to a first side in the second direction DR2, and the term “lower side” refers to a second side in the second direction DR2. The term “top” refers to one side in the third direction DR3, and the term “bottom” refers to the other side in the third direction DR3.

The display device 10 may have, for example, a square shape, in a plan view. In a case where the display device 10 is a TV, the display device 10 may have a rectangular shape whose long sides are aligned in the horizontal direction of the display device 10, but the present disclosure is not limited thereto. Alternatively, the display device 10 may have a rectangular shape whose long sides are aligned in the vertical direction of the display device 10 or may be rotatably installed such that the long sides of the display device 10 are variably aligned in the horizontal or vertical direction of the display device 10. Alternatively, the display device 10 may have a circular or elliptical shape.

The display device 10 may include a display area DPA and a non-display area NDA along an edge or periphery of the display area DPA. The display area DPA may be an active area where an image is displayed. The display area DPA may have a similar shape to the display device 10, for example, a square shape, in a plan view, but the present disclosure is not limited thereto.

The display area DPA may include a plurality of pixels PX. The pixels PX may be arranged in row and column directions. The pixels PX may have a rectangular or square shape in a plan view, but the present disclosure is not limited thereto. Alternatively, the pixels PX may have a rhombus shape having sides inclined with respect to the sides of the display device 10. The pixels PX may include pixels PX of various colors. For example, the pixels PX may include, but are not limited to, first-color pixels PX (e.g., red pixels PX), second-color pixels PX (e.g., green pixels PX), and third-color pixels PX (e.g., blue pixels PX). The pixels PX of the various colors may be alternately arranged in a stripe or PENTILE® arrangement structure, or the like. The PENTILE® pixel arrangement structure may be referred to as an RGBG matrix structure (e.g., a PENTILE® matrix structure or an RGBG structure (e.g., a PENTILE® structure)). PENTILE® is a registered trademark of Samsung Display Co., Ltd., Republic of Koreas.

The non-display area NDA may be disposed around the display area DPA. The non-display area NDA may surround the entire display area DPA or part of the display area DPA. The display area DPA may have a square shape, and the non-display area NDA may be disposed adjacent to the four sides of the display area DPA. The non-display area NDA may form the bezel of the display device 10.

Driving circuits or driving elements for driving the display area DPA may be disposed in the non-display area NDA. In part of the non-display area NDA adjacent to a first side (or the lower side) of the display device 10, a pad unit may be provided on a display substrate of the display device 10, and an external device EXD may be mounted on pad electrodes in the pad unit. Examples of the external device EXD include a connecting film, a printed circuit board (PCB), a driver integrated chip (DIC), a connector, and a wire connecting film. In part of the non-display area NDA adjacent to a second side (or the left side) of the display device 10, a scan driver SDR, which is directly formed on the display substrate of the display device 10, may be disposed.

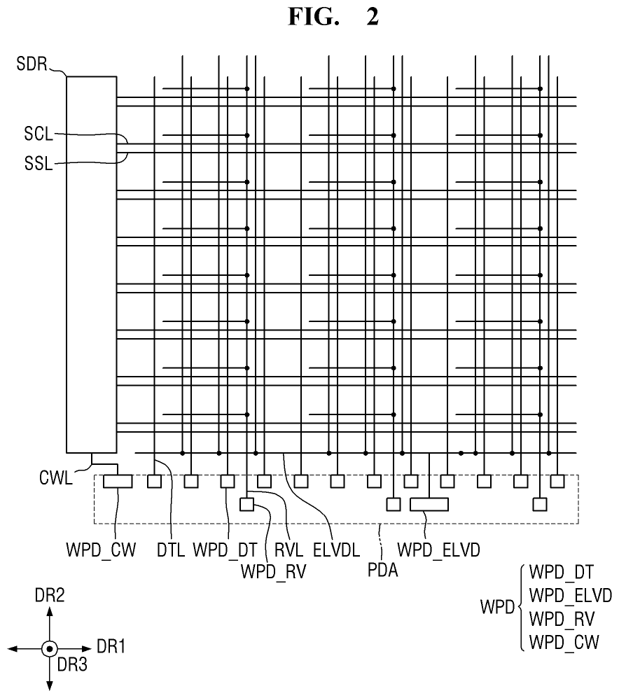

FIG. 2 is a layout view of the circuitry of the display substrate of the display device of FIG. 1.

Referring to FIG. 2, a plurality of lines are disposed on a first substrate. The plurality of lines may include scan lines SCL, sensing signal lines SSL, data lines DTL, reference voltage lines RVL, and a first power supply line ELVDL.

The scan lines SCL and the sensing signal lines SSL may extend in the first direction DR1. The scan lines SCL and the sensing signal lines SSL may be connected to a scan driving unit SDR. The scan driving unit SDR may include a scan driving circuit. The scan driving unit SDR may be disposed in the non-display area NDA, on one side of the display area DPA, but the present disclosure is not limited thereto. Alternatively, the scan driving unit SDR may be disposed in the non-display area NDA, on both sides of the display area DPA. The scan driving unit SDR may be connected to a signal connecting line CWL, and at least one end of the signal connecting line CWL may form a pad WPD_CW in the non-display area NDA and may be connected to the external device EXD of FIG. 1.

The data lines DTL and the reference voltage lines RVL may extend in the second direction DR2, which crosses the first direction DR1. The first power supply line ELVDL may include parts extending in the second direction DR2. The first power supply line ELVDL may further include parts extending in the first direction DR1. The first power supply line ELVDL may have a mesh structure, but the present disclosure is not limited thereto.

Wire pads WPD may be disposed at at least one end of each of the data lines DTL, the reference voltage lines RVL, and the first power supply line ELVDL. The wire pads WPD may be disposed in a pad unit PDA of the non-display area NDA. Wire pads WPD_DT (hereinafter, the data wire pads WPD_DT) of the data lines DTL, wire pads WPD_RV (hereinafter, the reference voltage pads WPD_RV) of the reference voltage lines RVL, and a wire pad WPD_ELVD (hereinafter, the first power supply pad WPD_ELVD) of the first power supply line ELVDL may be disposed in the pad unit PDA of the non-display area NDA. Alternatively, the data pads WPD_DT, the reference voltage pads WPD_RV, and the first power supply pad WPD_ELVD may be disposed in different parts of the non-display area NDA. As already mentioned above, the external device EXD of FIG. 1 may be mounted on the wire pads WPD. The external device EXD may be mounted on the wire pads WPD via anisotropic conductive films (ACFs) or ultrasonic bonding.

Each pixel PX on the display substrate includes a pixel driving circuit. The above-described lines may apply driving signals to the pixel driving circuit, passing by or through each pixel PX. The pixel driving circuit may include transistors and a capacitor. The numbers of transistors and capacitors included in the pixel driving circuit may vary. For example, the pixel driving circuit will hereinafter be described as having a “3T1C” structure including three transistors and one capacitor, but the present disclosure is not limited thereto. Alternatively, various other structures such as a “2T1 C”, “7T1 C”, or “6T1C” structure may also be applicable to the pixel driving circuit.

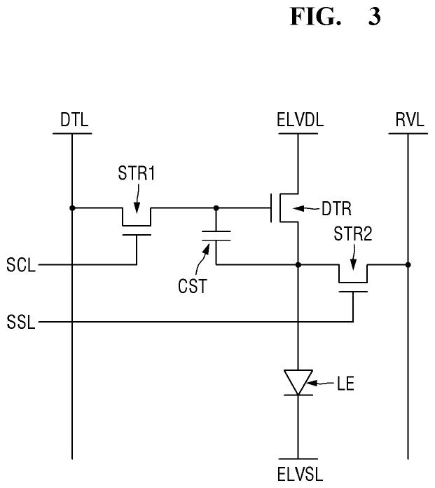

FIG. 3 is an equivalent circuit diagram of a pixel of the display device of FIG. 1.

Referring to FIG. 3, a pixel PX includes a light-emitting element LE, three transistors, i.e., a driving transistor DTR, a first transistor STR1, and a second transistor STR2, and one capacitor CST.

The light-emitting element LE emits light in accordance with a current applied thereto through the driving transistor DTR. The light-emitting element LE may be implemented as an inorganic light-emitting diode (LED), an OLED, a micro-LED, or a nano-LED.

A first electrode (or an anode) of the light-emitting element LE may be connected to a source electrode of the driving transistor DTR, a second electrode (or a cathode) of the light-emitting element LE may be connected to a second power supply line ELVSL, to which a low-potential voltage (or a second power supply voltage) is supplied. The second power supply voltage is lower than a high-potential voltage (or a first power supply voltage) supplied to the first power supply line ELVDL.

The driving transistor DTR controls a current flowing from the first power supply line ELVDL to the light-emitting element LE, in accordance with the difference in voltage between a gate electrode and the source electrode thereof. The gate electrode of the driving transistor DTR may be connected to a first electrode of the first transistor STR1, the source electrode of the driving transistor DTR may be connected to the first electrode of the light-emitting element LE, and a drain electrode of the driving transistor DTR may be connected to the first power supply line ELVDL, to which the first power supply voltage is supplied.

The first transistor STR1 is turned on by a scan signal from a scan line SCL to connect a data line DTL and the gate electrode of the driving transistor DTR. The gate electrode of the first transistor STR1 may be connected to the scan line SCL, the first electrode of the first transistor STR1 may be connected to the gate electrode of the driving transistor DTR, and a second electrode of the first transistor STR1 may be connected to a data line DTL.

The second transistor STR2 is turned on by a sensing signal from a sensing signal line SSL to connect the reference voltage line RVL and the source electrode of the driving transistor DTR. The gate electrode of the second transistor STR2 may be connected to the sensing signal line SSL, a first electrode of the second transistor STR2 may be connected to the reference voltage line RVL, and a second electrode of the second transistor STR2 may be connected to the source electrode of the driving transistor DTR.

The first electrodes of the first and second transistors STR1 and STR2 may be source electrodes, and the second electrodes of the first and second transistors STR1 and STR2 may be drain electrodes. Alternatively, the first electrodes of the first and second transistors STR1 and STR2 may be drain electrodes, and the second electrodes of the first and second transistors STR1 and STR2 may be source electrodes.

The capacitor CST is formed between the gate and source electrodes of the driving transistor DTR. The capacitor CST stores a differential voltage corresponding to the difference in voltage between the gate and source electrodes of the driving transistor DTR.

The driving transistor DTR and the first and second transistors STR1 and STR2 may be formed as thin-film transistors (TFTs). FIG. 3 illustrates that the driving transistor DTR and the first and second transistors STR1 and STR2 are N-type metal-oxide semiconductor field-effect transistors (N-MOSFETs), but the present disclosure is not limited thereto. Alternatively, the driving transistor DTR and the first and second transistors STR1 and STR2 may be P-type MOSFETs. Yet alternatively, some of the driving transistor DTR and the first and second transistors STR1 and STR2 may be P-type MOSFETs, and the other transistors may be N-type MOSFETs.

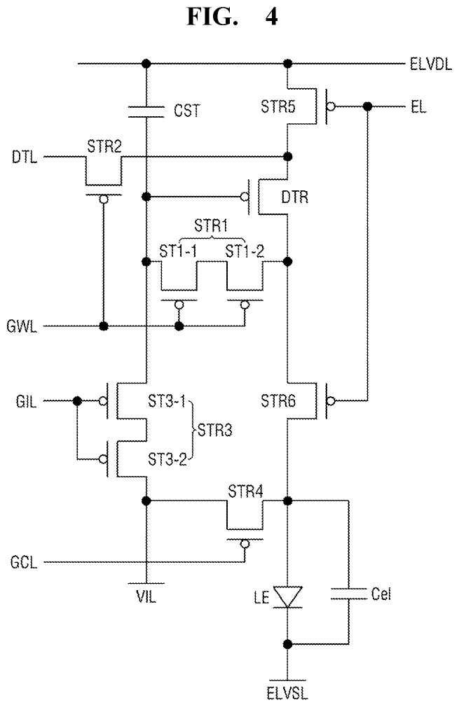

FIG. 4 is an equivalent circuit diagram of a pixel of a display device according to one or more embodiments of the present disclosure.

Referring to FIG. 4, a first electrode of a light-emitting element LE may be connected to a first electrode of a fourth transistor STR4 and a second electrode of a sixth transistor STR6, and a second electrode of the light-emitting element LE may be connected to a second power supply line ELVSL. A parasitic capacitor Cel may be formed between the first and second electrodes of the light-emitting element LE.

A pixel PX includes a driving transistor DTR, switching elements, and a capacitor CST. The switching elements include a first transistor STR1, a second transistor STR2, a third transistor STR3, the fourth transistor STR4, a fifth transistor STR5, and the sixth transistor STR6.

The driving transistor DTR includes a gate electrode, a first electrode, and a second electrode. The driving transistor DTR controls a drain-source current Ids (hereinafter, the driving current Ids) flowing between the first and second electrodes thereof.

The capacitor CST is formed between the gate electrode of the driving transistor DTR and a first power supply line ELVDL. A first electrode of the capacitor CST may be connected to the gate electrode of the driving transistor DTR, and a second electrode of the capacitor CST may be connected to the first power supply line ELVDL.

If the first electrodes of the first through sixth transistors STR1 through STR6 and the first electrode of the driving transistor DTR are source electrodes, the second electrodes of the first through sixth transistors STR1 through STR6 and the second electrode of the driving transistor DTR may be drain electrodes. Alternatively, if the first electrodes of the first through sixth transistors STR1 through STR6 and the first electrode of the driving transistor DTR are drain electrodes, the second electrodes of the first through sixth transistors STR1 through STR6 and the second electrode of the driving transistor DTR may be source electrodes.

Active layers of the first through sixth transistors STR1 through STR6 and an active layer of the driving transistor DTR may be formed of one of polysilicon, amorphous silicon, and an oxide semiconductor. For example, the active layers of the first through sixth transistors STR1 through STR6 and the active layer of the driving transistor DTR may be formed of polysilicon by a low-temperature polysilicon (LTPS) process.

FIG. 4 illustrates that the first through sixth transistors STR1 through STR6 and the driving transistor DTR are formed as P-type MOSFETs, but the present disclosure is not limited thereto. Alternatively, the first through sixth transistors STR1 through STR6 and the driving transistor DTR may be formed as N-type MOSFETs.

A first power supply voltage from the first power supply line ELVDL, a second power supply voltage from the second power supply line ELVSL, and a third power supply voltage from a third power supply line VIL may be set in consideration of the characteristics of the driving transistor DTR and the characteristics of the light-emitting element LE. In FIG. 4, a first transistor STR1 (that includes transistors ST1-1 and ST1-2) is connected between the capacitor CST and the driving transistor DTR, and has a gate (gates of the transistors ST1-1 and ST1-2) connected to the gate write line GWL. A second transistors STR2 is connected between a data transmission line DTL and the driving transistor DTR, and has a gate connected to the gate write line GWL. A third transistor STR3 (that includes transistors ST3-1 and ST3-2) is connected between the capacitor CST or the gate electrode of the driving transistor DTR and the third power supply line VIL, and has a gate (gates of the transistors ST3-1 and ST3-2) connected to the initialization scan line GIL. A fourth transistor is connected between the third power supply line VIL and the light-emitting element LE, and has a gate connected to the control scan line GCL. A firth transistor STR5 is connected between the first power supply line ELVDL and the driving transistor DTR and a sixth transistor is connected between the driving transistor DTR and the light-emitting element LE. The gates of the firth transistor STR5 and the sixth transistor STR6 may be connected to an emission line EL.

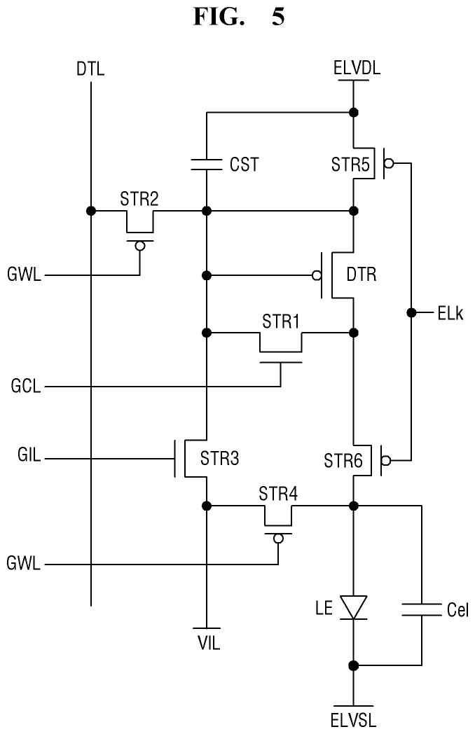

FIG. 5 is an equivalent circuit diagram of a pixel of a display device according to one or more embodiments of the present disclosure.

The embodiment of FIG. 5 differs from the embodiment of FIG. 4 in that a driving transistor DTR and second, fourth, fifth, and sixth transistors STR2, STR4, STR5, and STR6 are formed as P-type MOSFETs and first and third transistors STR1 and STR3 are formed as N-type MOSFETs.

Referring to FIG. 5, active layers of P-type MOSFETs, i.e., an active layer of the driving transistor DTR and active layers of the second, fourth, fifth, and sixth transistors STR2, STR4, STR5, and STR6, may be formed of polysilicon, and active layers of N-type MOSFETs, i.e., active layers of the first and third transistors STR1 and STR3, may be formed of an oxide semiconductor.

The embodiment of FIG. 5 also differs from the embodiment of FIG. 4 in that gate electrodes of the second and fourth transistors STR2 and STR4 are connected to a write scan line GWL and a gate electrode of the first transistor STR1 is connected to a control scan line GCL. As the first and third transistors STR1 and STR3 are formed as N-type MOSFETs, a scan signal having a gate-high voltage may be applied to the control scan line GCL and an initialization scan line GIL. On the contrary, as the second, fourth, fifth, and sixth transistors STR2, STR4, STR5, and STR6 are formed as P-type MOSFETs, a scan signal having a gate-low voltage may be applied to the write scan line GWL and an emission line EL.

The present disclosure is not limited to the equivalent circuit diagrams of FIGS. 3 through 5, and various other circuit configurations that are available to one of ordinary skill in the art, to which the present disclosure pertains, may also be employed.

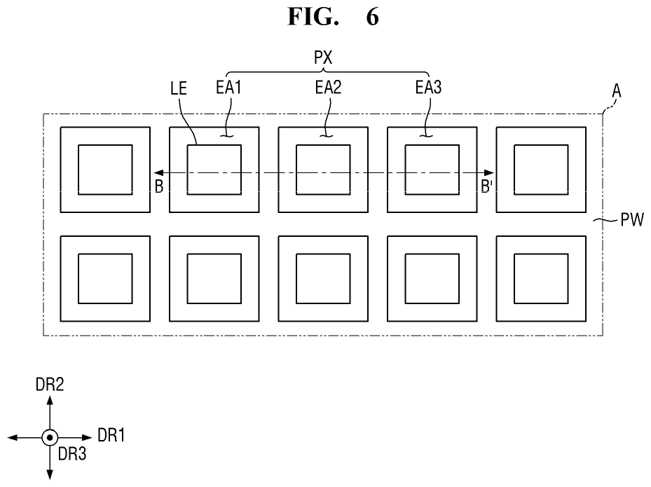

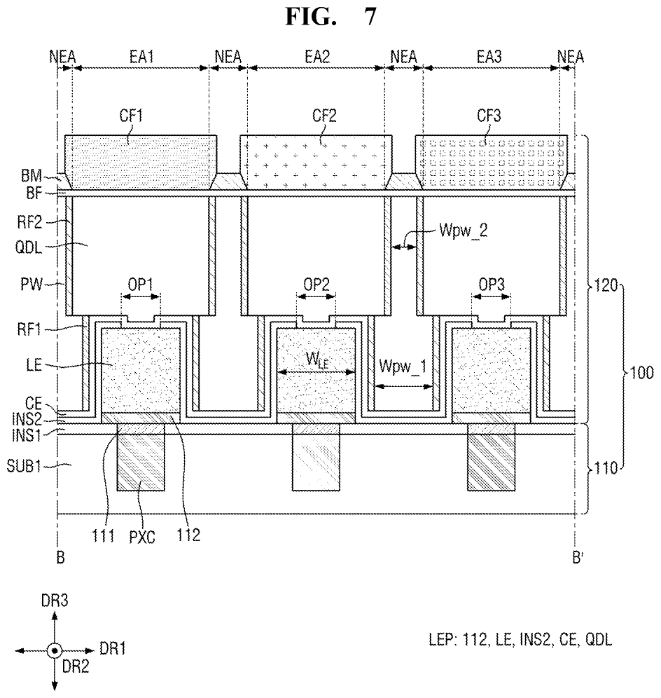

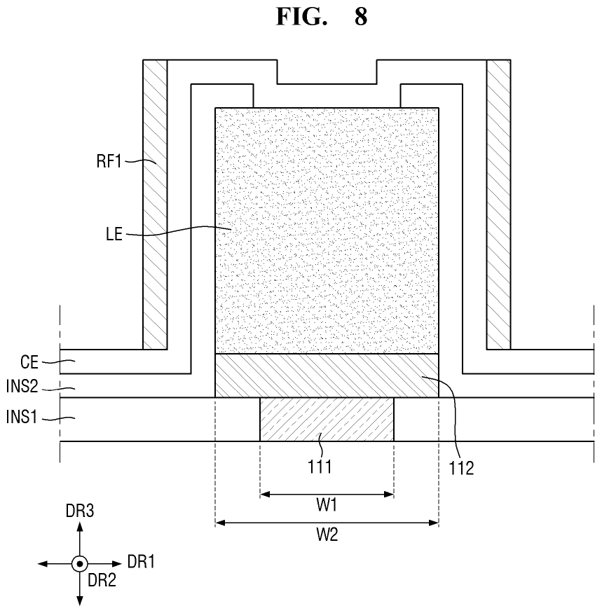

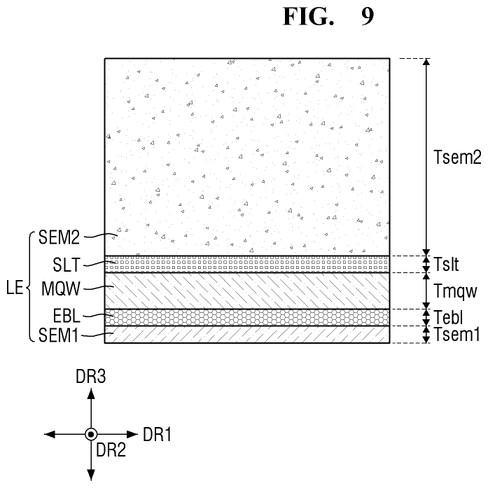

FIG. 6 is a layout view of an area A of FIG. 1, FIG. 7 is a cross-sectional view taken along the line B-B′ of FIG. 6, FIG. 8 is a cross-sectional view of a pixel electrode and a light-emitting element according to one or more embodiments of the present disclosure, and FIG. 9 is an enlarged cross-sectional view of the light-emitting element of FIG. 8.

Referring to FIGS. 1 and 6, the display area DPA of the display device 10 may include a plurality of pixels PX. The pixels PX may be defined as minimal units for emitting and displaying light.

Each of the pixels PX may include a plurality of emission areas (EA1, EA2, and EA3). FIGS. 6 and 7 illustrate that each of the pixels PX includes three emission areas (EA1, EA2, and EA3), i.e., first through third emission areas EA1 through EA3, but the present disclosure is not limited thereto. Alternatively, each of the pixels PX may include four emission areas.

Each of the emission areas (EA1, EA2, and EA3) of each of the pixels PX may include a light-emitting element LE. The light-emitting element LE may have a rectangular shape in a plan view, but the present disclosure is not limited thereto. Alternatively, the light-emitting element LE may have a non-quadrilateral polygonal shape, a circular shape, an elliptical shape, or an amorphous shape.

First emission areas EA1, second emission areas EA2, and third emission areas EA3 may be alternately arranged along the first direction DR1. For example, the first emission areas EA1, the second emission areas EA2, and the third emission areas EA3 may be arranged in the order of first, second, and third emission areas EA1, EA2, and EA3 along the first direction DR1.

The first emission areas EA1 may be arranged along the second direction DR2. The second emission areas EA2 may be arranged along the second direction DR2. The third emission areas EA3 may be arranged along the second direction DR2.

The emission areas (EA1, EA2, and EA3) may be divided by a partition wall PW. The partition wall PW may be disposed to be around (to surround) light-emitting elements LE. The partition wall PW may have a mesh shape, a fishnet shape, or a lattice shape in a plan view.

FIG. 6 illustrates that the emission areas (EA1, EA2, and EA3), which are defined by the partition wall PW, have a rectangular shape in a plan view, but the present disclosure is not limited thereto. Alternatively, the emission areas (EA1, EA2, and EA3) may have a non-quadrilateral polygonal shape, a circular shape, an elliptical shape, or an amorphous shape.

Referring to FIGS. 7 through 9, the display device 10 may include a semiconductor circuit substrate 110 and a light-emitting layer 120.

The semiconductor circuit substrate 110 may include a first substrate SUB1, a plurality of pixel circuit units PXC, pixel electrodes 111, and a first insulating layer INS1.

The first substrate SUB1 may be an insulating substrate. The first substrate SUB1 may include a transparent material. For example, the first substrate SUB1 may include a transparent insulating material such as glass or quartz. The first substrate SUB1 may be a rigid substrate, but the present disclosure is not limited thereto. In another example, the first substrate SUB1 may include plastic such as polyimide and may have flexibility such as bendability, foldability, or rollability. A plurality of emission areas (EA1, EA2, and EA3) and a non-emission area NEA may be defined on the first substrate SUB1.

The pixel circuit units PXC may be disposed in the first substrate SUB1. The pixel circuit units PXC may include complementary metal-oxide semiconductor (CMOS) circuits formed by a semiconductor process. Each of the pixel circuit units PXC may include at least one transistor formed by a semiconductor process. Each of the pixel circuit units PXC may further include at least one capacitor formed by a semiconductor process.

The pixel circuit units PXC may be disposed in the display area DPA. The pixel circuit units PXC may be connected to pixel electrodes 111. That is, the pixel circuit units PXC may be connected to the pixel electrodes 111 to correspond one-to-one to the pixel electrodes 111. The pixel circuit units PXC may apply pixel voltages or anode voltages to the pixel electrodes 111.

The pixel electrodes 111 may be disposed on the pixel circuit units PXC. The pixel electrodes 111 may be electrodes exposed from the pixel circuit units PXC. The pixel electrodes 111 may be integrally formed with the pixel circuit units PXC. The pixel electrodes 111 may be formed to have a width W1, which is smaller than the width of connecting electrodes 112, i.e., a width W2, but the present disclosure is not limited thereto. The pixel electrodes 111 may be formed to have a smaller width than light-emitting elements LE, but the present disclosure is not limited thereto. Alternatively, the pixel electrodes 111 may be formed to have the same width as the connecting electrodes 112. Also, the pixel electrodes 111 may be formed to have the same width as the light-emitting elements LE.

The connecting electrodes 112 may be formed to have a larger width (i.e., the width W2) than the width W1 of the pixel electrodes 111, i.e., the width W2, but the present disclosure is not limited thereto. Alternatively, the connecting electrodes 112 may have the same width as the pixel electrodes 111. The connecting electrodes 112 may have the same width as the light-emitting elements LE, but the present disclosure is not limited thereto.

The pixel electrodes 111 may receive pixel voltages or anode voltages from the pixel circuit units PXC. The pixel electrodes 111 may include tungsten (W), copper (Cu), titanium (Ti), silver (Ag), magnesium (Mg), aluminum (AI), platinum (Pt), lead (Pd), gold (Au), nickel (Ni), neodymium (Nd), iridium (Ir), chromium (Cr), lithium (Li), calcium (Ca), or a mixture thereof.

The first insulating layer INS1 may be disposed on parts of the first substrate SUB1 where the pixel electrodes 111 are not disposed. The first insulating layer INS1 may be disposed between the pixel electrodes 111. The top surface of the first insulating layer INS1 may be flatly connected to the top surfaces of the pixel electrodes 111. In other words, the top surface of the first insulating layer INS1 may be at a same level as the top surfaces of the pixel electrodes 111. The first insulating layer INS1 may be formed as an inorganic film such as a silicon oxide (SiO₂) film, an aluminum oxide (Al₂O₃) film, or a hafnium oxide (HfOₓ) film.

The light-emitting layer 120 may be a layer including the emission areas (EA1, EA2, and EA3) and emitting light. The light-emitting layer 120 may include the connecting electrodes 112, the light-emitting elements LE, a second insulating layer INS2, a common electrode CE, wavelength conversion layers QDL, the partition wall PW, first reflective layers RF1, second reflective layers RF2, and a plurality of color filters (CF1, CF2, and CF3). Here, the connecting electrodes 112, the light-emitting elements LE, the second insulating layer INS2, the common electrode CE, and the wavelength conversion layers QDL may be collectively referred to as light-emitting element units LEP.

The connecting electrodes 112 may be disposed on the pixel electrodes 111. That is, the connecting electrodes 112 may be connected to the pixel electrodes 111 to correspond one-to-one to the pixel electrodes 111. The connecting electrodes 112 may be formed to have a larger width (i.e., the width W2) than the width W1 of the pixel electrodes 111, but the present disclosure is not limited thereto. Alternatively, the connecting electrodes 112 may have the same width as the pixel electrodes 111. The connecting electrodes 112 may have the same width as the light-emitting elements LE, but the present disclosure is not limited thereto.

The connecting electrodes 112 may function as bonding metals for bonding the pixel electrodes 111 and the light-emitting elements LE during the fabrication of the display device 10. For example, the connecting electrodes 112 may include at least one of Au, Cu, tin (Sn), Ag, Al, and Ti.

The light-emitting elements LE may be disposed in first, second, and third emission areas EA1, EA2, and EA3. The light-emitting elements LE may be vertical LEDs extending in the third direction DR3. That is, the length, in the third direction DR3, of the light-emitting elements LE may be greater than the length, in a horizontal direction, of the light-emitting elements LE. Here, the length, in the horizontal direction, of the light-emitting elements LE may refer to the length, in the first or second direction DR1 or DR2, of the light-emitting elements LE. For example, the length, in the third direction DR3, of the light-emitting elements LE may be about 1 μm to about 5 μm.

The light-emitting elements LE may be micro-LEDs. Referring to FIG. 9, a light-emitting element LE includes a first semiconductor layer SEM1, an electron blocking layer EBL, an active layer MQW, a superlattice layer SLT, and a second semiconductor layer SEM2 arranged along the third direction DR3. The first semiconductor layer SEM1, the electron blocking layer EBL, the active layer MQW, the superlattice layer SLT, and the second semiconductor layer SEM2 may be sequentially stacked in the third direction DR3.

The light-emitting element LE may have a cylindrical shape that extends longer latitudinally than longitudinally, a disk shape, or a rod shape, but the present disclosure is not limited thereto. Alternatively, the light-emitting element LE may have a wire shape, a tube shape, a polygonal prism shape (such as a cube shape, a cuboid shape, or a hexagonal prism shape), or various other shapes such as a shape extending in one direction with outer sides partially inclined.

The first semiconductor layer SEM1 may be disposed on a connecting electrode 112. The first semiconductor layer SEM1 may be doped with a dopant of a first conductivity type such as magnesium (Mg), zinc (Zn), Ca, selenium (Se), or barium (Ba). For example, the first semiconductor layer SEM1 may be p-GaN doped with Mg, which is a p-type dopant. A thickness Tsem1 of the first semiconductor layer SEM1 may be about 30 nm to about 200 nm.

The electron blocking layer EBL may be disposed on the first semiconductor layer SEM1. The electron blocking layer EBL may be a layer suppressing or preventing the flow of too many electrons into the active layer MQW. For example, the electron blocking layer EBL may be p-AlGaN doped with Mg, which is a p-type dopant. A thickness Tebl of the electron blocking layer EBL may be about 10 nm to about 50 nm. In one or more embodiments, the electron blocking layer EBL may not be provided.

The active layer MQW may be disposed on the electron blocking layer EBL. The active layer MQW may emit light through the combination of electron-hole pairs in accordance with electric signals applied thereto from the first and second semiconductor layers SEM1 and SEM2. The active layer MQW may emit first light having a central wavelength band of 450 nm to 495 nm, i.e., blue-wavelength light, but the present disclosure is not limited thereto.

The active layer MQW may include a material having a single or multi-quantum well structure. In a case where the active layer MQW includes a material having a multi-quantum well structure, the active layer MQW may have a structure in which a plurality of well layers and a plurality of barrier layers are alternately stacked. The well layers may be formed of, but is not limited to, InGaN, and the barrier layers may be formed of, but is not limited to, GaN or AlGaN. The thickness of the well layers may be about 1 nm to about 4 nm, and the thickness of the barrier layers may be about 3 nm to about 10 nm.

Alternatively, the active layer MQW may have a structure in which semiconductor materials having a large bandgap energy and semiconductor materials having a small bandgap energy are alternately stacked or may include a Group III semiconductor material or a Group V semiconductor material depending on the wavelength band of light to be emitted by the active layer MQW. Light emitted by the active layer MQW is not limited to the first light, and in one or more embodiments, the active layer MQW may emit second light (or green-wavelength light) or third light (or red-wavelength light).

The superlattice layer SLT may be disposed on the active layer MQW. The superlattice layer SLT may be a layer for alleviating the stress between the second semiconductor layer SEM2 and the active layer MQW. For example, the superlattice layer SLT may be formed of InGaN or GaN. A thickness Tslt of the superlattice layer SLT may be about 50 nm to about 200 nm. In one or more embodiments, the superlattice layer SLT may not be provided.

The second semiconductor layer SEM2 may be disposed on the superlattice layer SLT. The second semiconductor layer SEM2 may be doped with a dopant of a second conductivity type such as silicon (Si), germanium (Ge), or Sn. For example, the second semiconductor layer SEM2 may be n-GaN doped with Si. A thickness Tsem2 of the second semiconductor layer SEM2 may be about 500 nm to about 1 μm.

Referring again to FIGS. 7 through 9, the second insulating layer INS2 may be disposed on the top surface and the sides of each of the light-emitting elements LE, the sides of each of the connecting electrodes 112, and the parts of the first insulating layer INS1 where the connecting electrodes 112 are not disposed. The second insulating layer INS2 may not cover the entire top surfaces of the light-emitting elements LE. The second insulating layer INS2 may include a plurality of openings (OP1, OP2, and OP3), which expose the tops of the light-emitting elements LE. The openings (OP1, OP2, and OP3) may include first, second, and third openings OP1, OP2, and OP3, which overlap with the first, second, and third emission areas EA1, EA2, and EA3, respectively. The second insulating layer INS2 may cover the entire tops of the light-emitting elements LE except for the openings (OP1, OP2, and OP3). The second insulating layer INS2 may be formed as an inorganic film such as a SiO₂ film, an Al₂O₃ film, or a HfOₓ film, but the present disclosure is not limited thereto.

As the common electrode CE is disposed on the entire first substrate SUB1 and a common voltage is applied to the common electrode CE, the common electrode CE may include a low-resistance material. The common electrode CE may be disposed on the second insulating layer INS2. The common electrode CE may be electrically connected to the light-emitting elements LE through the openings (OP1, OP2, and OP3). The common electrode CE may be disposed to completely cover the light-emitting elements LE. The common electrode CE may be formed to be thin enough to properly transmit light therethrough. The common electrode CE may include a transparent conductive material. For example, the common electrode CE may include a transparent conductive oxide (TCO) such as indium tin oxide (ITO) or indium zinc oxide (IZO). The thickness of the common electrode CE may be about 10 Å to about 200 Å, but the present disclosure is not limited thereto.

The wavelength conversion layers QDL may be disposed on the common electrode CE, in the first, second, and third emission areas EA1, EA2, and EA3. The wavelength conversion layers QDL may overlap with the light-emitting elements LE in the third direction DR3, in the first, second, and third emission areas EA1, EA2, and EA3.

The wavelength conversion layers QDL may include first wavelength conversion particles. The first wavelength conversion particles may convert first light, emitted from the light-emitting elements LE, to fourth light. For example, the first wavelength conversion particles may convert blue-wavelength light to yellow-wavelength light. The first wavelength conversion particles may be quantum dots (QDs), quantum rods, a fluorescent material, or a phosphorescent material. The QDs may include Group IV nanocrystals, Group II-VI compound nanocrystals, Group III-V compound nanocrystals, Group IV-VI nanocrystals, or a combination thereof.

The QDs may include cores and shells overcoating the cores. For example, the cores may be, but are not limited to, at least one of CdS, CdSe, CdTe, ZnS, ZnSe, ZnTe, GaN, GaP, GaAs, GaSb, AlN, AIP, AlAs, AlSb, InP, InAs, InSb, SiC, Ca, Se, In, P, Fe, Pt, Ni, Co, Al, Ag, Au, Cu, FePt, Fe₂O₃, Fe₃O₄, Si, and Ge. For example, the shells may be, but are not limited to, at least one of ZnS, ZnSe, ZnTe, CdS, CdSe, CdTe, HgS, HgSe, HgTe, AlN, AlP, AlAs, AlSb, GaN, GaP, GaAs, GaSb, GaSe, InN, InP, InAs, InSb, TIN, TIP, TIAs, TISb, PbS, PbSe, and PbTe.

The wavelength conversion layers QDL may further include a scatterer for scattering light, emitted from the light-emitting elements LE, in random directions. In this case, the scatterer may be particles of a metal oxide or an organic material. Here, the metal oxide may be, for example, titanium oxide (TO₂), zirconium oxide (ZrO₂), silicon dioxide (SiO₂), aluminum oxide (Al₂O₃), indium oxide (In₂O₃), zinc oxide (ZnO), or tin oxide (SnO₂), and the organic material may be, for example, an acrylic resin or a urethane resin. The scatterer may have a diameter of several nanometers to dozens of nanometers.

The partition wall PW may be disposed between the light-emitting elements LE and between the wavelength conversion layers QDL. The partition wall PW may divide the emission areas (EA1, EA2, and EA3) and the non-emission area NEA. The partition wall PW may be formed in the entire display area DPA as a lattice pattern. The partition wall PW may overlap with the non-emission area NEA, but not with the emission areas (EA1, EA2, and EA3).

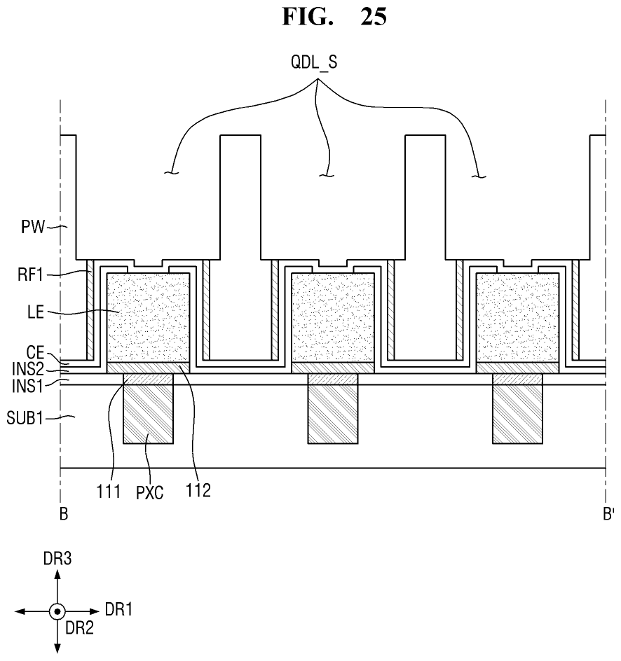

The partition wall PW may provide spaces QDL-S (e.g., see FIG. 25) in which the wavelength conversion layers QDL are to be formed. That is, the partition wall PW may define regions of the wavelength conversion layers QDL. The partition wall PW may be formed of an organic insulating material to have a suitable thickness (e.g., a predetermined thickness). The organic insulating material may be, for example, an epoxy resin, an acrylic resin, a cardo resin, or an imide resin. A width Wpw_1 of the partition wall PW between the light-emitting elements LE may be the same as, or less than, a width WLE, in the first direction DR1, of the light-emitting elements LE.

The first reflective layers RF1 may overlap with the sides of each of the light-emitting elements LE and may be disposed on the common electrode CE. The first reflective layers RF1 may be positioned between the partition wall PW and the common electrode CE.

The first reflective layers RF1 may reflect light emitted from the light-emitting elements LE laterally, rather than upwardly. The first reflective layers RF1 may include a metallic material with high reflectance, such as Al. The first reflective layers RF1 may have a thickness of about 0.1 μm.

The second reflective layers RF2 may be disposed on the sides of each of the spaces QDL-S provided by the partition wall PW. The second reflective layers RF2 may be disposed on the sides of each part of the partition wall PW and the sides of each of the wavelength conversion layers QDL and may be positioned between the partition wall PW and the wavelength conversion layers QDL. That is, the second reflective layers RF2 may be in contact with the sides of each of the wavelength conversion layers QDL and with the partition wall PW. The second reflective layers RF2 may overlap with the non-emission area NEA. The second reflective layers RF2 may include a metallic material with high reflectance, such as Al. The second reflective layers RF2 may have a thickness of about 0.1 μm. The first reflective layers RF1 and the second reflective layers RF2 may be formed of the same material, but the present disclosure is not limited thereto.

The second reflective layers RF2 may be disposed in the non-emission area NEA, which overlaps with the partition wall PW, to prevent the mixture of colors between the emission areas (EA1, EA2, and EA3).

The light-emitting element LE in the first emission area EA1 may emit first light, e.g., blue light, the light-emitting element LE in the second emission area EA2 may emit second light, e.g., red light, and the light-emitting element LE in the third emission area EA3 may emit third light, e.g., green light. A light-blocking member BM located between the emission areas (EA1, EA2, and EA3) prevents the mixture of colors between the emission areas (EA1, EA2, and EA3).

The color filters (CF1, CF2, and CF3) may be disposed on the partition wall PW and the wavelength conversion layers QDL. The color filters (CF1, CF2, and CF3) may be disposed to overlap with the pixel circuit units PXC and the wavelength conversion layers QDL. The color filters (CF1, CF2, and CF3) may include first, second, and third color filters CF1, CF2, and CF3.

The first color filter CF1 may be disposed on the wavelength conversion layer QDL in the first emission area EA1. The first color filter CF1 may transmit first light therethrough and may absorb or block second light or third light. For example, the first color filter CF1 may transmit blue-wavelength light therethrough and may absorb or block green or red-wavelength light.

The second color filter CF2 may be disposed on one of the wavelength conversion layer QDL in the second emission area EA2. The second color filter CF2 may transmit second light therethrough and may absorb or block first light or third light. For example, the second color filter CF2 may transmit green-wavelength light therethrough and may absorb or block blue or red-wavelength light.

The third color filter CF3 may be disposed on the wavelength conversion layer QDL in the third emission area EA3. The third color filter CF3 may transmit third light therethrough and may absorb or block first light or second light. For example, the third color filter CF3 may transmit red-wavelength light therethrough and may absorb or block blue or green-wavelength light.

The color filters (CF1, CF2, and CF3) may have the same area as, or a larger area than, the emission areas (EA1, EA2, and EA3). For example, the first color filter CF1 may have the same area as, or a larger area than, the first emission area EA1, the second color filter CF2 may have the same area as, or a larger area than, the second emission area EA2, and the third color filter CF3 may have the same area as, or a larger area than, the third emission area EA3.

The light-blocking member BM may be disposed on the partition wall PW. The light-blocking member BM may overlap with the non-emission area NEA and may block the transmission of light. The light-blocking member BM, like the partition wall PW, may substantially have a lattice shape in a plan view. The light-blocking member BM may be disposed to overlap with the partition wall PW, but not with the emission areas (EA1, EA2, and EA3).

The light-blocking member BM may include an organic light-blocking material and may be formed by coating and exposing the organic light-blocking material. The light-blocking member BM may include a light-blocking pigment or dye and may be a black matrix. The light-blocking member BM may overlap at least partially with the color filters (CF1, CF2, and CF3), and the color filters (CF1, CF2, and CF3) may be disposed on at least parts of the light-blocking member BM.

In a case where the light-blocking member BM is disposed on the partition wall PW, at least some external light is absorbed by the light-blocking member BM. Thus, the distortion of colors that may be caused by the reflection of external light can be reduced. Also, the light-blocking member BM can prevent light from infiltrating between adjacent emission areas to cause the mixture of colors, and as a result, the color reproducibility of the display device 10 can be further improved.

A buffer layer BF may be disposed below the color filters (CF1, CF2, and CF3) and the light-blocking member BM. The buffer layer BF may be disposed on the partition wall PW and the wavelength conversion layers QDL. A surface of the buffer layer BF, for example, the top surface of the buffer layer BF, may be in contact with the bottom surfaces of the color filters (CF1, CF2, and CF3) and the bottom surface of the light-blocking member BM. The other surface of the buffer layer BF, for example, the bottom surface of the buffer layer BF, may be in contact with the top surface of the partition wall PW and the top surfaces of the wavelength conversion layers QDL. The buffer layer BF may include an inorganic insulating material. For example, the buffer layer BF may include silicon oxide (SiOₓ), silicon nitride (SiNₓ), silicon oxynitride (SiOₓN_{y}), aluminum oxide (AlₓO_{y}), or aluminum nitride (AlN), but the present disclosure is not limited thereto. For example, the buffer layer BF may have a width of 0.01 μm to 1 μm, but the present disclosure is not limited thereto. In one or more embodiments, the buffer layer BF may not be provided.

Display devices according to one or more embodiments of the present disclosure will hereinafter be described.

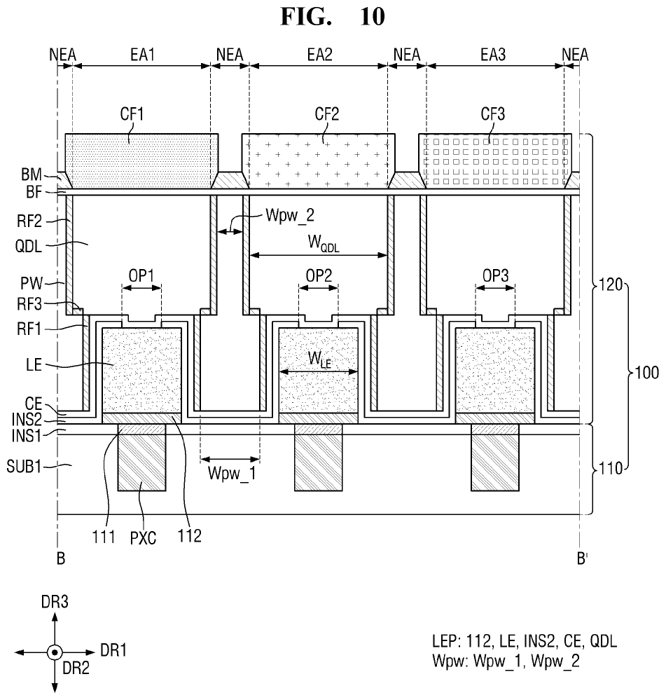

FIG. 10 is a cross-sectional view of a display device according to one or more embodiments of the present disclosure.

Referring to FIG. 10, the embodiment of FIG. 10 differs from the embodiment of FIGS. 6 through 8 in that third reflective layers RF3 are further disposed at the bottoms of wavelength conversion layers QDL. The embodiment of FIG. 10 will hereinafter be described, focusing mainly on the difference(s) with the embodiment of FIGS. 6 through 8.

A length W_{QOL}, in a first direction DR1, of the wavelength conversion layers QDL may be greater than a length WLE, in the first direction DR1, of light-emitting elements LE. A width Wpw_1 of a partition wall PW between the light-emitting elements LE may be greater than a width Wpw_2 of the partition wall PW between the wavelength conversion layers QDL.

The third reflective layers RF3 may be disposed at the bottoms of parts of the wavelength conversion layers QDL that do not overlap with the light-emitting elements LE. First reflective layers RF1 and second reflective layers RF2 may be disposed to extend in second and third directions DR2 and DR3, but the third reflective layers RF3 may be disposed to extend in the first and second directions DR1 and DR2. The third reflective layers RF3 may be disposed in emission areas (EA1, EA2, and EA3). The third reflective layers RF3 may be in contact with the partition wall PW and the wavelength conversion layers QDL. The third reflective layers RF3 may be formed of the same material as the first reflective layers RF1 and the second reflective layers RF2, but the present disclosure is not limited thereto. The third reflective layers RF3 may include a metallic material with high reflectance, such as Al. The third reflective layers RF3 may have a thickness of about 0.1 μm.

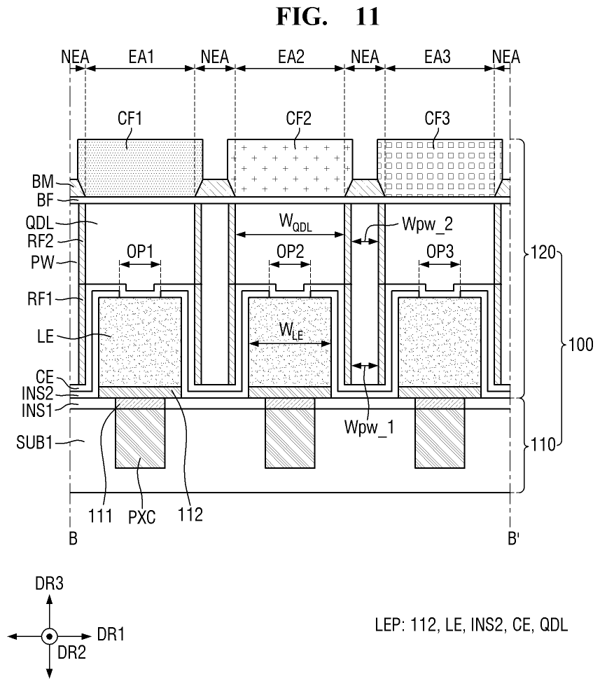

FIG. 11 is a cross-sectional view of a display device according to one or more embodiments of the present disclosure.

Referring to FIG. 11, the embodiment of FIG. 11 differs from the embodiment of FIGS. 7 and 8 in that the thicknesses of wavelength conversion layers QDL and a partition wall PW are generally reduced and a width Wpw_1 of the partition wall PW between light-emitting elements LE is the same as a width Wpw_2 of the partition wall between the wavelength conversion layers QDL. The embodiment of FIG. 11 will hereinafter be described, focusing mainly on the difference(s) with the embodiment of FIGS. 7 and 8.

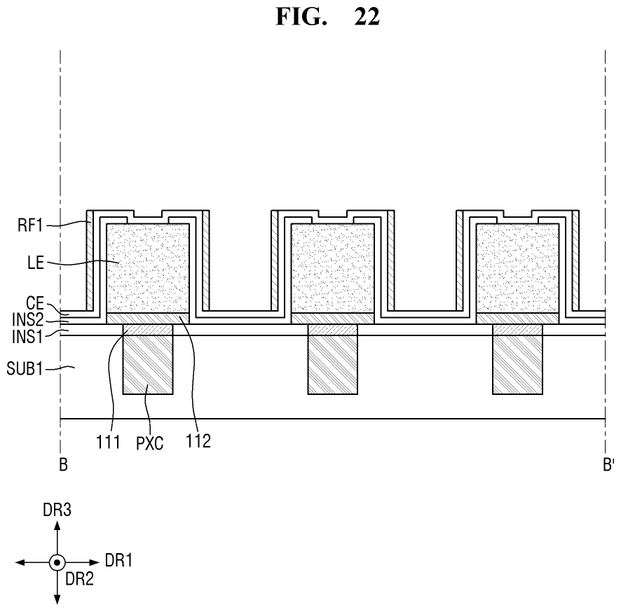

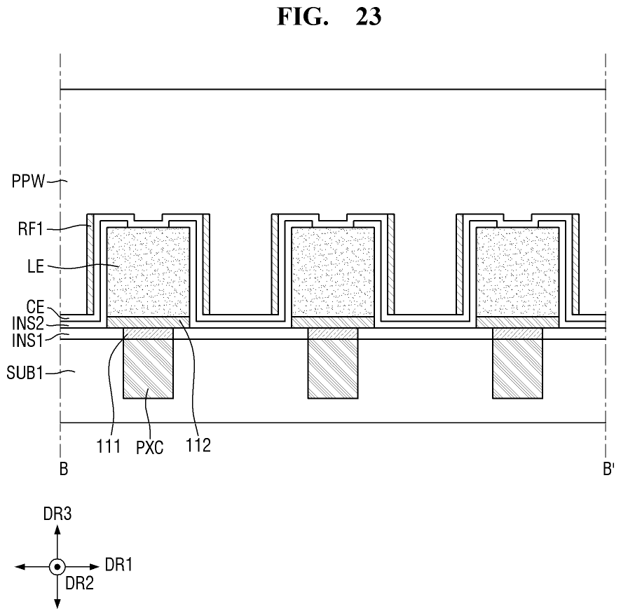

As will be described later with reference to FIGS. 22 and 23, during the formation of the partition wall PW, a first substrate SUB1 where the light-emitting elements LE are formed is covered with an organic insulating material, in consideration of the thickness of the wavelength conversion layers QDL. Thereafter, a partition wall PW is formed by etching areas above the light-emitting elements LE where the wavelength conversion layers QDL are to be disposed. Thus, the width and the height of the partition wall PW may be designed in consideration of the width and the height of the wavelength conversion layers QDL by using etching mask patterns.

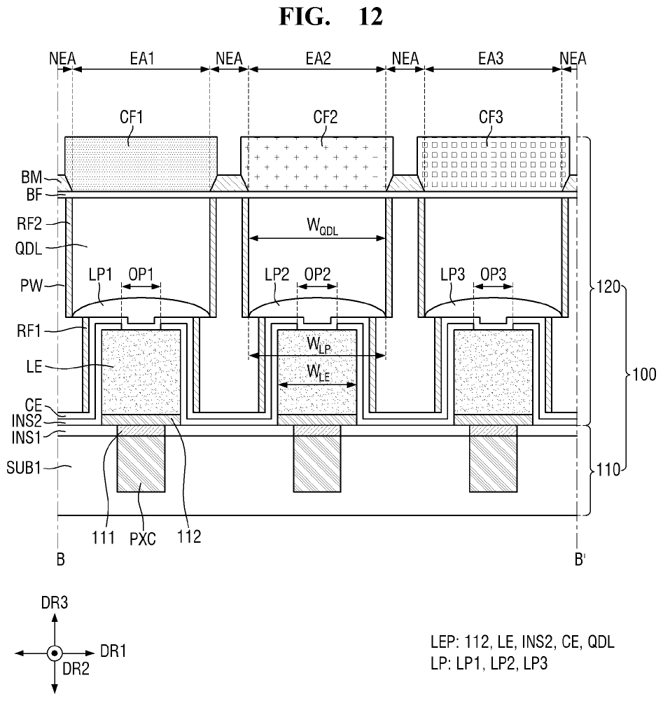

FIG. 12 is a cross-sectional view of a display device according to one or more embodiments of the present disclosure.

Referring to FIG. 12, the embodiment of FIG. 12 differs from the embodiment of FIGS. 7 and 8 in that lenses LP are disposed on light-emitting elements LE. The embodiment of FIG. 12 will hereinafter be described, focusing mainly on the difference(s) with the embodiment of FIGS. 7 and 8.

The lenses LP may be disposed on the light-emitting elements LE. One lens LP may be disposed on one light-emitting element LE. The lenses LP may overlap with emission areas (EA1, EA2, and EA3). A first lens LP1 may be disposed in a first emission area EA1, a second lens LP2 may be disposed in a second emission area EA2, and a third lens LP3 may be disposed in a third emission area EA3.

The lenses LP may condense light emitted from light-emitting elements LE and may thus allow the light to proceed upwardly. The condensation of light emitted from the light-emitting elements LE into the middle of each of the emission areas (EA1, EA2, and EA3) can be reliably performed by controlling the refractive index of the lens LP to be greater than the refractive index of the wavelength conversion layers QDL and forming the lenses LP as converging lenses for use in condensing light. That is, the lenses LP may protrude in a third direction DR3 from the top surfaces of the light-emitting elements LE. For example, the lenses LP may have a hemispherical shape that protrudes in an upward direction, in a cross-sectional view.

A width W_{LP} of the lenses LP may be greater than a width W_{LE} of the light-emitting elements LE and less than a width W_{QOL} of the wavelength conversion layers QDL.

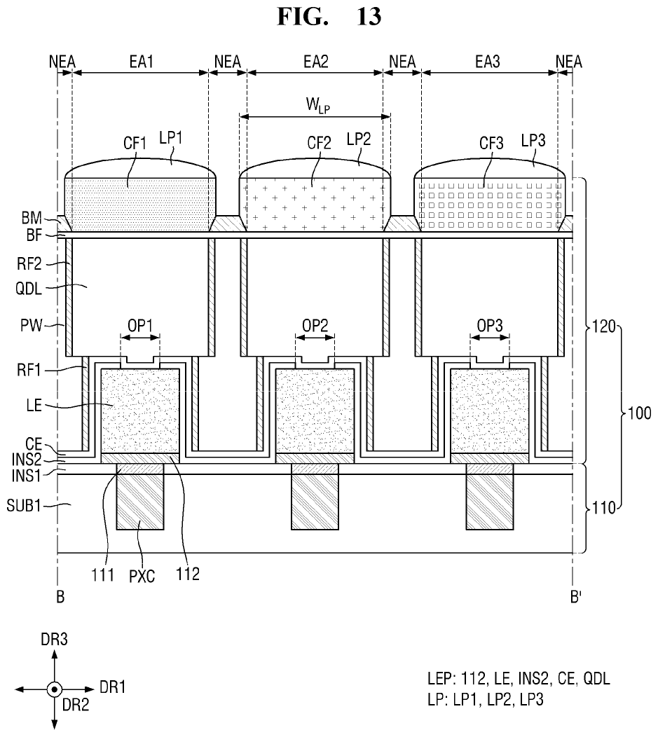

FIG. 13 is a cross-sectional view of a display device according to one or more embodiments of the present disclosure.

Referring to FIG. 13, the embodiment of FIG. 13 differs from the embodiment of FIGS. 7 and 8 in that lenses LP are disposed on color filters (CF1, CF2, and CF3). The embodiment of FIG. 13 will hereinafter be described, focusing mainly on the difference(s) with the embodiment of FIGS. 7 and 8.

The lenses LP may be disposed on color filters (CF1, CF2, and CF3). One lens LP may be disposed on one color filter. The lenses LP may overlap with emission areas (EA1, EA2, and EA3). A first lens LP1 may be disposed on a first color filter CF1, a second lens LP2 may be disposed on a second color filter CF2, and a third lens LP3 may be disposed on a third color filter CF3.

The lenses LP may condense light emitted from light-emitting elements LE and may thus allow the light to proceed upwardly. The condensation of light transmitted through the color filters (CF1, CF2, and CF3) into the middle of each of the emission areas (EA1, EA2, and EA3) can be reliably performed by controlling the refractive index of the lens LP to be greater than the refractive index of the color filters (CF1, CF2, and CF3), which are adjacent to the lenses LP, and forming the lenses LP as converging lenses for use in condensing light. That is, the lenses LP may protrude in a third direction DR3 from the top surfaces of the color filters (CF1, CF2, and CF3). For example, the lenses LP may have a hemispherical shape that protrudes in an upward direction, in a cross-sectional view.

A width W_{LP} of the lenses LP may be the same as, or less than a width W_{QOL} of the color filters (CF1, CF2, and CF3) (e.g., see FIG. 12).

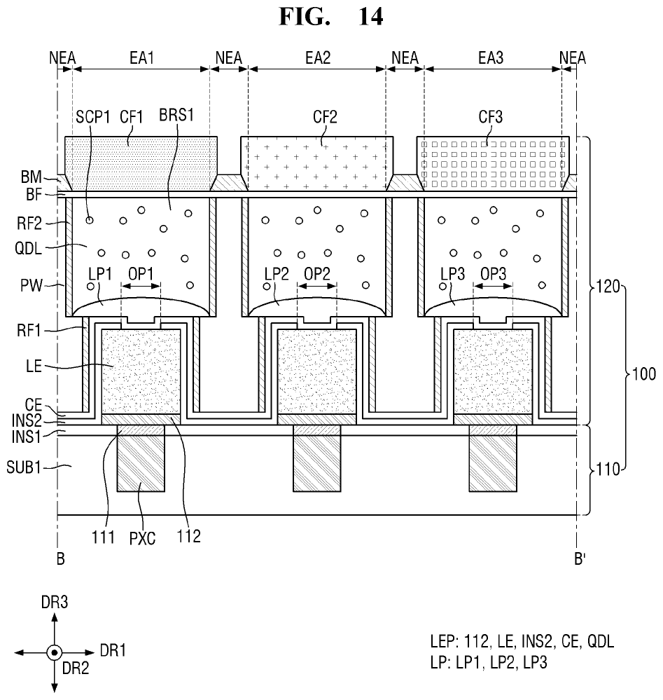

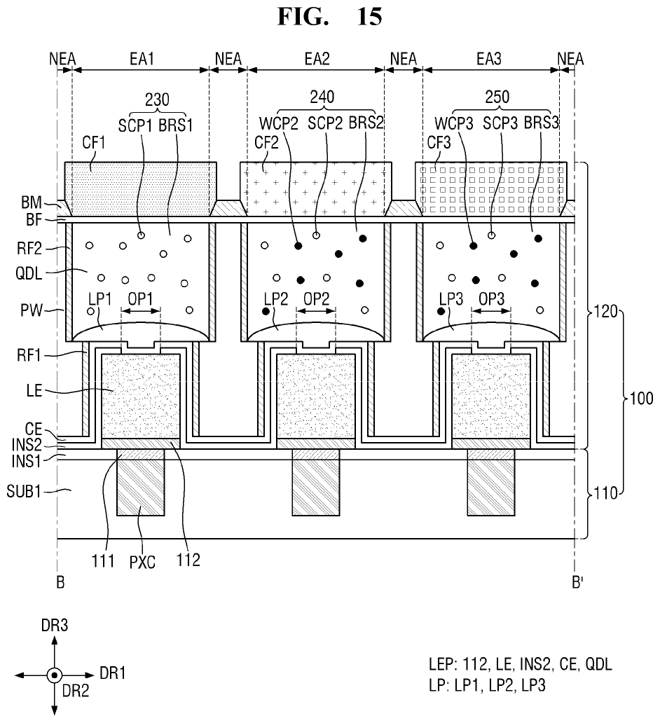

FIG. 14 is a cross-sectional view of a display device according to one or more embodiments of the present disclosure, and FIG. 15 is a cross-sectional view of a display device according to one or more embodiments of the present disclosure.

Referring to FIG. 14, a light-emitting element LE in a first emission area EA1 may emit first light, e.g., blue light, a light-emitting element LE in a second emission area EA2 may emit second light, e.g., red light, and a light-emitting element LE in a third emission area EA3 may emit third light, e.g., green light. In this case, as wavelength conversion layers QDL include a first scatterer SCP1 and a first base resin BRS1, the wavelength conversion layers QDL can scatter light emitted from the light-emitting elements LE and can emit the light through color filters (CF1, CF2, and CF3).

Referring to FIG. 15, light-emitting elements LE in first, second, and third emission areas EA1, EA2, and EA3 may emit first light, e.g., blue light. In this case, wavelength conversion layers QDL may include a light-transmitting pattern 230, which overlaps with the first emission area EA1, a first wavelength conversion pattern 240, which overlaps with the second emission area EA2, and a second wavelength conversion pattern 250, which overlaps with the third emission area EA3.

The light-transmitting pattern 230 may be disposed to overlap with the first emission area EA1 and the first color filter CF1. The light-transmitting pattern 230 may transmit incident light therethrough. The first light emitted from the light-emitting element LE in the first emission area EA1 may be blue light. The first light emitted from the light-emitting element LE in the first emission area EA1 may be emitted toward the first emission area EA1 through the light-transmitting pattern 230. The light-transmitting pattern 230 may include a first base resin BRS1 and a first scatterer SCP1, which is dispersed in the first base resin BRS1. The first base resin BRS1 and the first scatterer SCP1 are as already described above, and thus, detailed descriptions thereof will be omitted.

The first wavelength conversion pattern 240 may overlap with the second emission area EA2 and a second color filter CF2. The first wavelength conversion pattern 240 may convert or shift the peak wavelength of incident light to a desired peak wavelength (e.g., a predetermined peak wavelength) and may emit the peak wavelength-converted (or shifted) light. The first wavelength conversion pattern 240 may convert first light emitted from the light-emitting element LE in the second emission area EA2 to second light having a single peak wavelength of about 610 nm to about 650 nm, for example, red light.

The first wavelength conversion pattern 240 may include a second base resin BRS2 and second wavelength conversion particles WCP2 and a second scatterer SCP2, which are dispersed in the second base resin BRS2.

The second base resin BRS2 may be formed of a material with high light transmittance and may include the same material as the first base resin BRS1.

The second wavelength conversion particles WCP2 may convert or shift the peak wavelength of the incident light to a desired peak wavelength (e.g., a predetermined peak wavelength). The second wavelength conversion particles WCP2 may convert the first light emitted from the light-emitting element LE in the second emission area EA2 to second light having a single peak wavelength of about 610 nm to about 650 nm, for example, red light. Examples of the second wavelength conversion particles WCP2 include quantum dots, quantum rods, and phosphors. The second wavelength conversion particles WCP2 may be substantially the same as, or similar to, third wavelength conversion particles WCP3, and thus, a detailed description thereof will be omitted.

Some of the first light emitted from the light-emitting element LE in the second emission area EA2 may not be converted to second light or red light, but may be transmitted through the first wavelength conversion pattern 240. The first light transmitted through the first wavelength conversion pattern 240 may be blocked by the second color filter CF2. The red light obtained by the first wavelength conversion pattern 240 from the first light emitted from the light-emitting element LE in the second emission area EA2 may be emitted to the outside through the second color filter CF2.

The second wavelength conversion pattern 250 may overlap with the third emission area EA3 and a third color filter CF3. The second wavelength conversion pattern 250 may convert or shift the peak wavelength of the incident light to a desired peak wavelength (e.g., a predetermined peak wavelength) and may emit the peak wavelength-converted (or shifted) light. The second wavelength conversion pattern 250 may convert first light emitted from the light-emitting element LE in the third emission area EA3 to third light having a single peak wavelength of about 510 nm to about 550 nm, for example, green light.

The second wavelength conversion pattern 250 may include a third base resin BRS3 and third wavelength conversion particles WCP3 and a third scatterer SCP3, which are dispersed in the third base resin BRS3.

The third base resin BRS3 may be formed of a material with high light transmittance and may include the same material as the first and second base resins BRS1 and BRS2 or at least one of the above-mentioned example materials for forming the first base resin BRS1.

The third wavelength conversion particles WCP3 may convert or shift the peak wavelength of the incident light to a desired peak wavelength (e.g., a predetermined peak wavelength). The third wavelength conversion particles WCP3 may convert the first light emitted from the light-emitting element LE in the third emission area EA3 to third light having a single peak wavelength of about 510 nm to about 550 nm, for example, green light.

Examples of the third wavelength conversion particles WCP3 include quantum dots, quantum rods, and phosphors. The third wavelength conversion particles WCP3 may be substantially the same as, or similar to, the second wavelength conversion particles WCP2, and thus, a detailed description thereof will be omitted.

Some of the first light emitted from the light-emitting element LE in the third emission area EA3 may not be converted to third light or green light and may be blocked by the third color filter CF3. The green light obtained by the second wavelength conversion pattern 250 from the first light emitted from the light-emitting element LE in the third emission area EA3 may be emitted to the outside through the third color filter CF3.

As wavelength conversion layers QDL including the light-transmitting pattern 230, the first wavelength conversion pattern 240, and the second wavelength conversion pattern 250 are formed, the light emission efficiency of a display device 10 for blue light, green light, and red light can be improved.

Referring to FIG. 15, the embodiment of FIG. 15 differs from the embodiment of FIG. 14 in that the first and second wavelength conversion patterns 240 and 250 include the second wavelength conversion particles WCP2 and the third wavelength conversion particles WCP2, respectively.

In one or more embodiments, the first and second wavelength conversion patterns 240 and 250 may include first wavelength conversion particles WCP1, which convert first light or blue light to fourth light or yellow light. Thus, first light or blue light emitted from the light-emitting elements LE in the second and third emission areas EA2 and EA3 may be converted to fourth light or yellow light. First light or blue light may be mixed with fourth light or yellow light in each of the first and second wavelength conversion patterns 240 and 250 so that fifth light or white light may be emitted. Then, the fifth light may be converted to, and emitted as, second light by the second color filter CF2, and may be converted to, and emitted as, third light by the third color filter CF3.

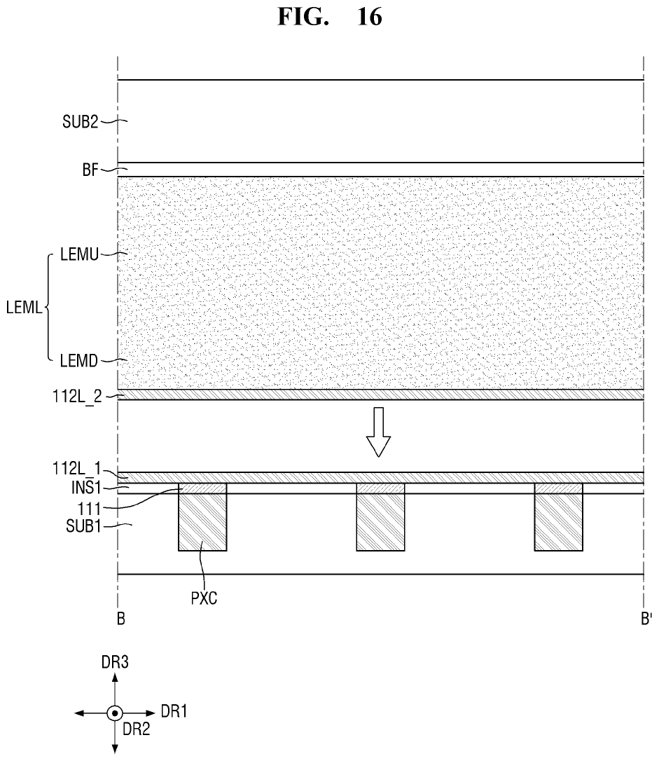

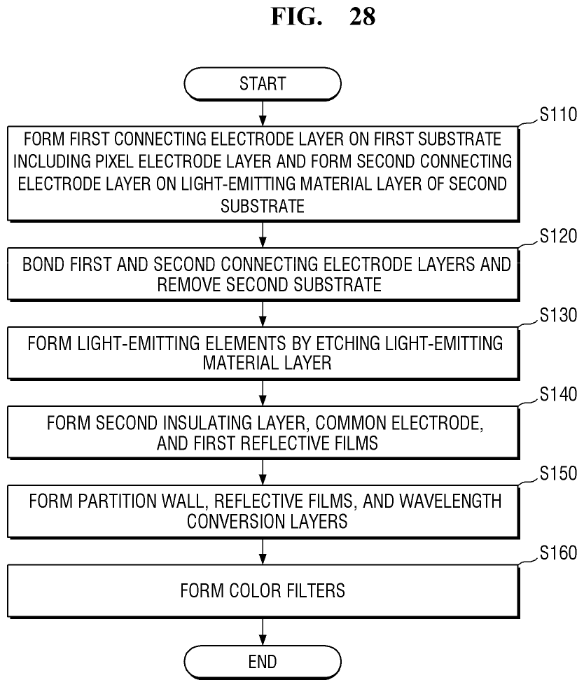

FIGS. 16 through 27 are cross-sectional views illustrating a method of fabricating a display device according to one or more embodiments of the present disclosure, and FIG. 28 is a flowchart illustrating the method of fabricating a display device according to one or more embodiments of the present disclosure.

Referring to FIGS. 16 and 28, a first insulating layer INS1 and pixel electrodes 111 are formed on a first substrate SUB1 including pixel circuit units PXC, and a first connecting electrode layer 112L_1 is formed on the first insulating layer INS1 and the pixel electrodes 111, and a second connecting electrode layer 112L_2 is formed on a light-emitting material layer LEML of a second substrate SUB2 (S110).

Specifically, the pixel electrodes 111 are formed on the pixel circuit units PXC, and the first insulating layer INS1 is formed on parts of the first substrate SUB1 where the pixel electrodes 111 are not disposed. The top surface of the first insulating layer INS1 may be flatly connected to the top surfaces of the pixel electrodes 111. That is, the difference in height between the top surface of the first substrate SUB1 and the pixel electrodes 111 may be removed by the first insulating layer INS1. The first insulating layer INS1 may be formed as an inorganic film such as a SiO₂ film, an Al₂O₃ film, or a HfOₓ film.

Thereafter, the first connecting electrode layer 112L_1 is deposited on the pixel electrodes 111 and the first insulating layer INS1. The first connecting electrode layer 112L_1 may include at least one of Au, Cu, Sn, Ag, Al, and Ti.

A buffer layer BF may be formed on one surface of the second substrate SUB2. The second substrate SUB2 may be a silicon substrate or a sapphire substrate.

The buffer layer BF may be formed as an inorganic film such as a SiO₂ film, an Al₂O₃ film, or a HfOₓ film.

The light-emitting material layer LEML may be disposed on the buffer layer BF. The light-emitting material layer LEML may include first and second semiconductor material layers LEMD and LEMU. The second semiconductor material layer LEMU may be disposed on the buffer layer BF, and the first semiconductor material layer LEMD may be disposed on the second semiconductor material layer LEMU. The thickness of the second semiconductor material layer LEMU may be greater than the thickness of the first semiconductor material layer LEMD.

The first semiconductor material layer LEMD may include a first semiconductor layer SEM1, an electron blocking layer EBL, an active layer MQW, a superlattice layer SLT, and a second semiconductor layer SEM2, as illustrated in FIG. 9. The second semiconductor material layer LEMU may be an undoped semiconductor layer. For example, the second semiconductor material layer LEMU may be an undoped GaN layer.

The second connecting electrode layer 112L_2 may be deposited on the first semiconductor material layer LEMD. The second connecting electrode layer 112L_2 may include at least one of Au, Cu, Sn, Ag, Al, and Ti.

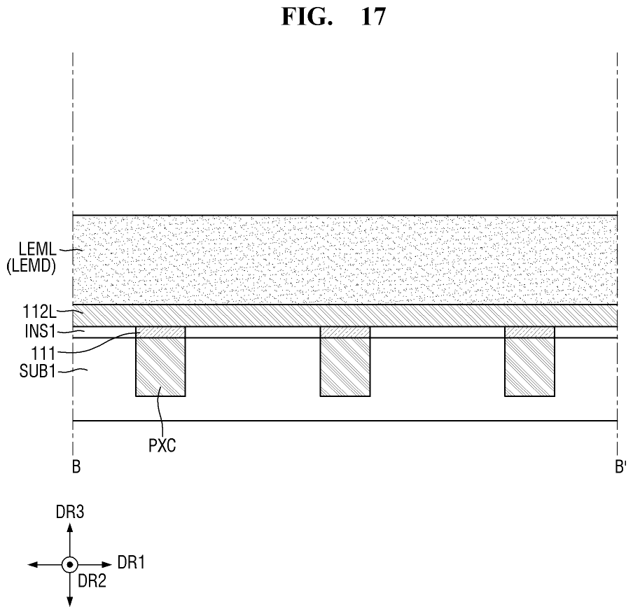

Thereafter, referring to FIGS. 17 and 28, the first and second connecting electrode layers 112L_1 and 112L_2 are bonded together, and the second substrate SUB2 is removed (S120).

Specifically, the first connecting electrode layer 112L_1 of the first substrate SUB1 and the second connecting electrode layer 112L_2 of the second substrate SUB2 are placed in contact with each other. Thereafter, the first and second connecting electrode layers 112L_1 and 112L_2 are fusion-bonded at a suitable temperature (e.g., a predetermined temperature), thereby forming single connecting electrodes 112. That is, the connecting electrodes 112 are disposed between the pixel electrodes 111 of the first substrate SUB1 and the light-emitting material layer LEML of the second substrate SUB2 and function as bonding metals for bonding the pixel electrodes 111 of the first substrate SUB1 and the light-emitting material layer LEML of the second substrate SUB2.

Thereafter, the second substrate SUB2 and the buffer layer BF may be removed by a polishing process such as chemical mechanical polishing (CMP) and/or an etching process. Also, the second semiconductor material layer LEMU of the light-emitting material layer LEML may be removed by a polishing process such as CMP.

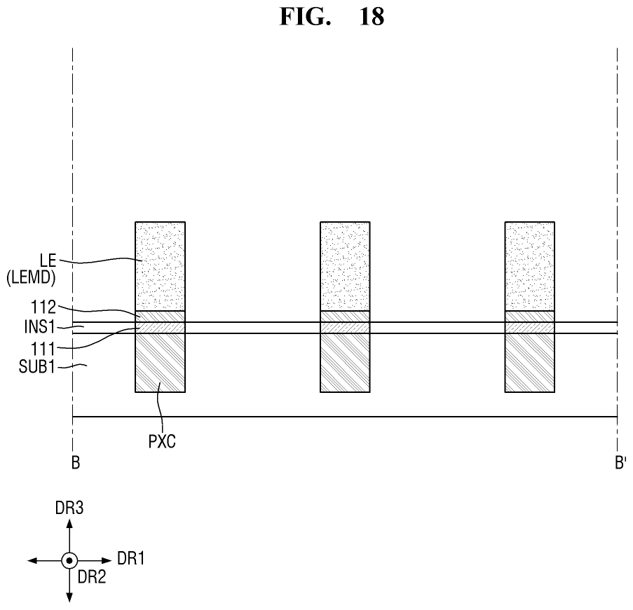

Referring to FIGS. 18 and 28, light-emitting elements LE are formed by etching the light-emitting material layer LEML (S130).

Specifically, mask patterns are formed on the top surface of the light-emitting material layer LEML. The top surface of the light-emitting material layer LEML may be the top surface of the first light-emitting material layer LEMD exposed by the removal of the second substrate SUB2, the buffer layer BF, and the second light-emitting material layer LEMU. The mask patterns may be disposed in regions where the light-emitting elements LE are to be formed. The mask patterns may overlap with the pixel electrodes 111 in a third direction DR3. The mask patterns may include a conductive material such as Ni. The mask patterns may have a thickness of about 0.01 μm to about 1 μm.

The mask patterns may not be etched away by an etching material for etching the light-emitting material layer LEML. Accordingly, parts of the light-emitting material layer LEML where the mask patterns are disposed may not be etched away. As a result, the light-emitting elements LE may be formed on the top surfaces of the pixel electrodes 111. Thereafter, the mask patterns are removed.

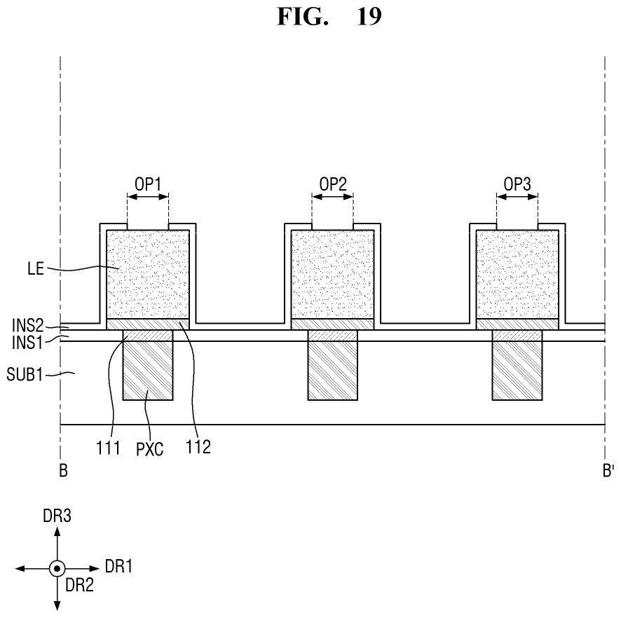

Thereafter, referring to FIGS. 19 through 22 and 28, a second insulating layer INS2, a common electrode CE, and first reflective layers RF1 are formed (S140).

Specifically, the second insulating layer INS2 is deposited to cover the entire surface of the first substrate SUB1 where the light-emitting elements LE are disposed. Thereafter, openings (OP1, OP2, and OP3) are formed on the light-emitting elements LE by using photoresist. Thereafter, as illustrated in FIG. 19, the second insulating layer INS2 may be deposited on the entire top surfaces of the light-emitting elements LE, except for the openings (OP1, OP2, and OP3), on the sides of each of the light-emitting elements LE, the sides of each of the connecting electrodes 112, and on parts of the first insulating film INS1 where the light-emitting elements LE are not disposed, and the tops of the light-emitting elements LE may be exposed through the openings (OP1, OP2, and OP3).

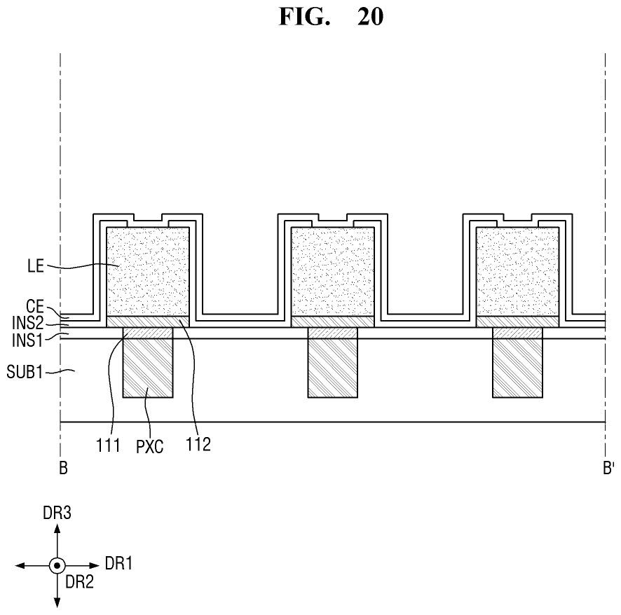

Thereafter, as illustrated in FIG. 20, the common electrode CE is deposited on the second insulating layer INS2 and on parts of the top surfaces of the light-emitting elements LE not covered by the second insulating layer INS2. The common electrode CE may include a TCO such as ITO or IZO.

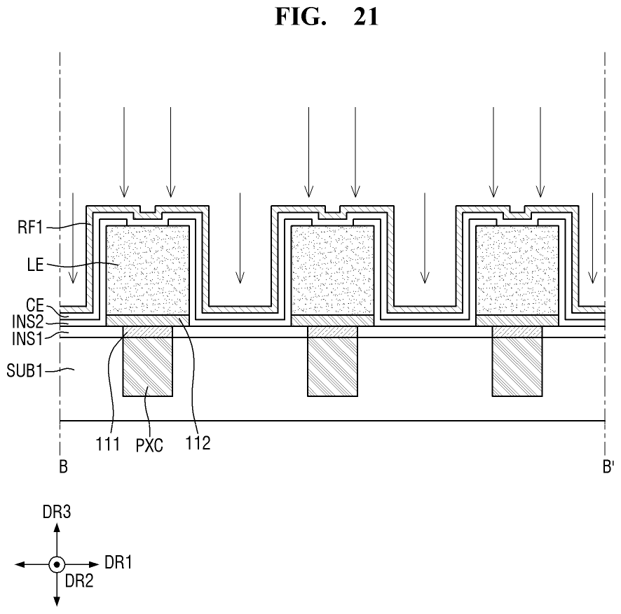

Thereafter, as illustrated in FIG. 21, the first reflective layers RF1 are deposited to cover the common electrode CE. Thereafter, a large voltage difference is formed in the third direction DR3 without the need of an additional mask, and the first reflective layers RF1 are etched by an etching material. In this case, the first reflective layers RF1 may be etched with the etching material by moving the etching material in the third direction DR3, i.e., in a top-to-bottom direction, via voltage control. As a result, parts of the first reflective layers RF1 on a horizontal plane defined by the first and second directions DR1 and DR2 may be removed, but parts of the first reflective layers RF1 on a vertical plane defined by the third direction DR3 may not be removed. Thus, the first reflective layers RF1 may be removed from the top surface of the common electrode CE, in the non-emission area NEA and the first, second, and third emission areas EA1, EA2, and EA3. Thus, parts of the first reflective layers RF1 on the sides of each of the light-emitting elements LE may not be removed. Accordingly, the first reflective layers RF1 may be disposed on parts of the common electrode CE overlapping with the sides of each of the light-emitting elements LE.

Thereafter, referring to FIGS. 23 through 26 and 28, a partition wall PW, second reflective layers RF2, and wavelength conversion layers QDL are formed (S150).

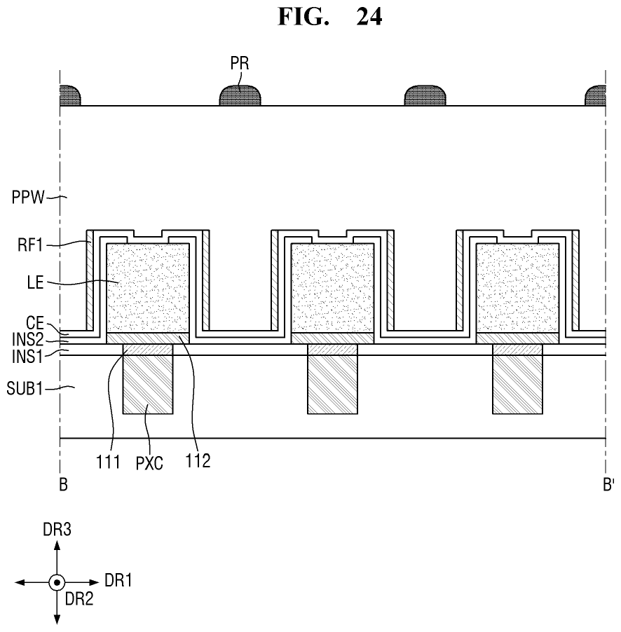

Specifically, as illustrated in FIG. 23, an organic insulating material PPW is applied on the light-emitting elements LE where the first reflective layers RF1 are formed. Thereafter, as illustrated in FIG. 24, mask patterns PR are disposed in the non-emission area NEA, and patterning is performed. Thereafter, as illustrated in FIG. 25, as the non-emission area NEA is protected from etching, the partition wall PW may be formed, and spaces QDL-S where the wavelength conversion layers QDL are to be formed may be formed in the first, second, and third emission areas EA1, EA2, and EA3 where the mask patterns PR are not disposed. The top of the common electrode CE is exposed at the bottoms of the spaces QDL-S. Thereafter, the mask patterns PR are removed.

Thereafter, reflective layers RF are deposited to cover the first substrate SUB1 where the partition wall and the spaces QDL-S are formed. A large voltage difference is formed in the third direction DR3 without the need of an additional mask, and the reflective layers RF are etched by an etching material. As a result, the reflective layers RF may be removed from the top surfaces of the light-emitting elements LE, on the partition wall PW and in the first, second, and third emission areas EA1, EA2, and EA3. Parts of the reflective layers RF on the sides of each part of the partition wall PW may not be removed. Accordingly, the reflective layers RF may be disposed on the sides of each part of the partition wall PW, in the first, second, and third emission areas EA1, EA2, and EA3.

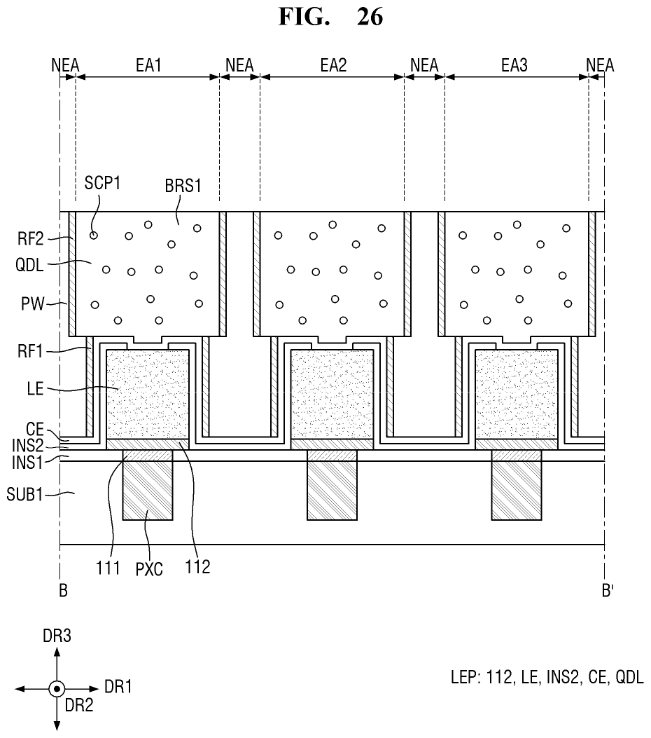

Thereafter, referring to FIG. 26, the wavelength conversion layers QDL are formed in the spaces QDL-S, between parts of the partition wall PW. The wavelength conversion layers QDL may be formed to fill the spaces QDL-S. The wavelength conversion layers QDL may be formed by a solution process, such as inkjet printing or imprinting, using a solution obtained by mixing a first scatterer SCP1 in a first base resin BRS1, but the present disclosure is not limited thereto. The wavelength conversion layers QDL may be formed in the spaces QDL-S to overlap with the first, second, and third emission areas EA1, EA2, and EA3.

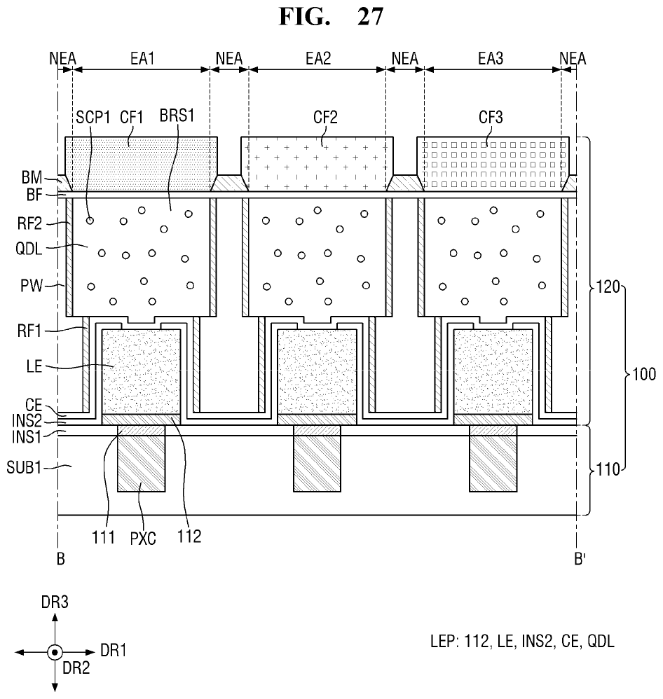

Referring to FIGS. 27 and 28, a plurality of color filters (CF1, CF2, and CF3) are formed (S160).

A buffer layer BF may be further formed before the formation of the color filters (CF1, CF2, and CF3).

The buffer layer BF is formed to cover the partition wall PW and the wavelength conversion layers QDL. One surface of the buffer layer BF, for example, the top surface of the buffer layer BF, may be in contact with the bottom surfaces of the color filters (CF1, CF2, and CF3) and the bottom surface of a light-blocking member BM. Also, the other surface of the buffer layer BF, for example, the bottom surface of the buffer layer BF, may be in contact with the top surface of the partition wall PW and the top surfaces of the wavelength conversion layers QDL. The buffer layer BF may include an inorganic insulating material. For example, the buffer layer BF may include SiOₓ, SiNₓ, SiOₓN_{y}, AlₓO_{y}, or AlN, but the present disclosure is not limited thereto. In one or more embodiments, the buffer layer BF may not be provided.

Thereafter, the light-blocking member BM is formed on the partition wall PW. The light-blocking member BM is formed by applying and patterning a light-blocking material. The light-blocking member BM is formed to overlap with the non-emission area NEA, but not with the first, second, and third emission areas EA1, EA2, and EA3. Thereafter, a first color filter CF1 is formed on one of the wavelength conversion layers QDL, divided by the light-blocking member BM. The first color filter CF1 may be formed by a photo process. The first color filter CF1 may be formed to have a thickness of 1 μm, but the present disclosure is not limited thereto. Similarly, other color filters may also be formed via patterning to overlap with their respective openings.

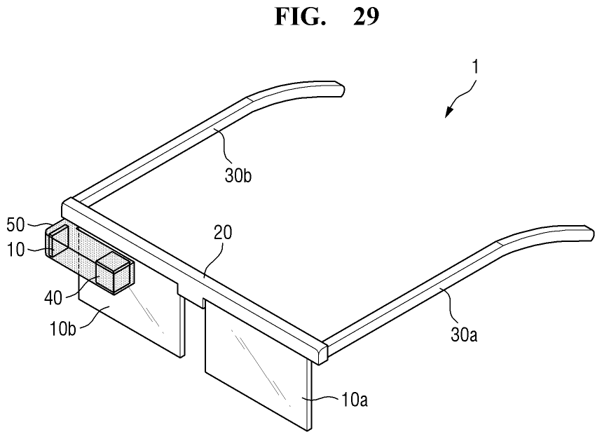

FIG. 29 is an example diagram showing a virtual reality device including a display device according to one or more embodiments. FIG. 29 shows a virtual reality device 1 to which the display device 10 according to one or more embodiments is applied.

Referring to FIG. 29, the virtual reality device 1 according to one or more embodiments may be a device in a form of glasses. The virtual reality device 1 according to one or more embodiments may include a display device 10, a left-eye lens 10a, a right-eye lens 10b, a support frame 20, left and right legs 30a and 30b, a reflective member 40, and a display device housing 50.

FIG. 29 exemplifies the virtual reality device 1 including the two legs 30a and 30b. The present disclosure is not limited thereto. The virtual reality device 1 according to one or more embodiments may be applied to a head mounted display including a head mounted band that may be mounted on a head instead of the legs 30a and 30b. That is, the virtual reality device 1 according to one or more embodiments may not be limited to the example shown in FIG. 29, and may be applied in various forms and in various electronic devices.

The display device housing 50 may receive the display device 10 and the reflective member 40. An image displayed on the display device 10 may be reflected from the reflective member 40 and provided to a user's right-eye through the right-eye lens 10b. Thus, the user may view a virtual reality image displayed on the display device 10 via the right-eye.

FIG. 29 illustrates that the display device housing 50 is disposed at a right end of the support frame 20. However, embodiments of the present disclosure are not limited thereto. For example, the display device housing 50 may be disposed at a left end of the support frame 20. In this case, the image displayed on the display device 10 may be reflected from the reflective member 40 and provided to the user's left-eye via the left-eye lens 10a. Thus, the user may view the virtual reality image displayed on the display device 10 via the left-eye. Alternatively, the display device housing 50 may be disposed at each of the left end and the right end of the support frame 20. In this case, the user may view the virtual reality image displayed on the display device 10 via both the left-eye and the right-eye.

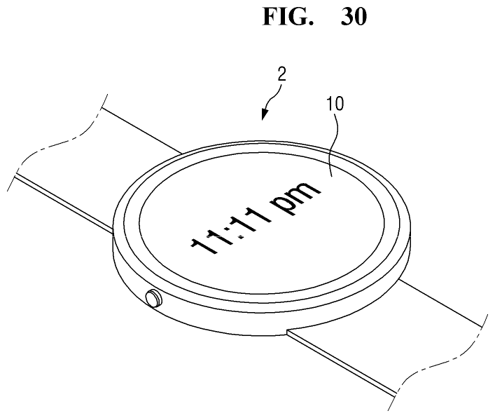

FIG. 30 is an example diagram showing a smart device including a display device according to one or more embodiments.

Referring to FIG. 30, a display device 10 according to one or more embodiments may be applied to a smart watch 2 as one of smart devices.

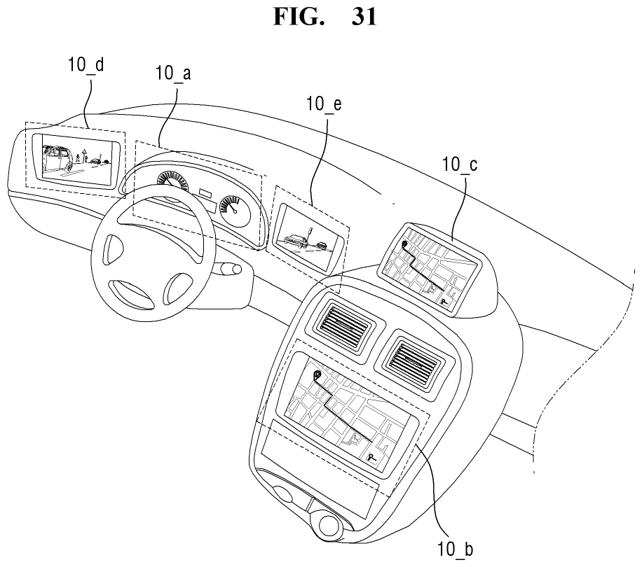

FIG. 31 is a diagram showing a vehicle including a display device according to one or more embodiments. FIG. 31 shows a vehicle to which display devices according to one or more embodiments are applied.

Referring to FIG. 31, the display devices 10_a, 10_b, and 10_c according to one or more embodiments may be applied to the dashboard of the vehicle, applied to the center fascia of the vehicle, or applied to a Center Information Display (CID) disposed on the dashboard of the vehicle. Further, each of the display devices 10_d and 10_e according to one or more embodiments may be applied to each room mirror display that replaces each of side mirrors of the vehicle.

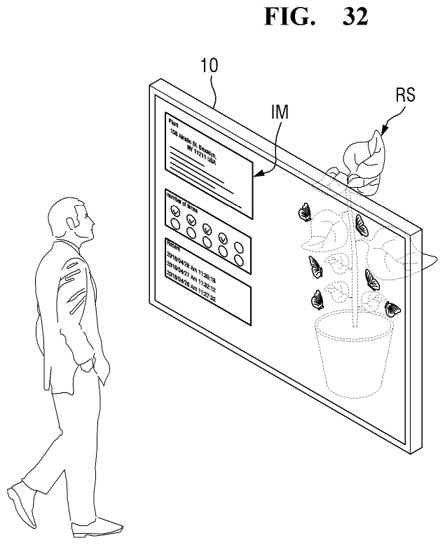

FIG. 32 is one example diagram showing a transparent display device including a display device according to one or more embodiments.

Referring to FIG. 32, a display device according to one or more embodiments may be applied to a transparent display device. The transparent display device may transmit light therethrough while displaying an image IM thereon. Therefore, a user located in front of the transparent display device may not only view the image IM displayed on the display device 10, but also see an object RS or a background located in rear of the transparent display device. When the display device 10 is applied to the transparent display device, the semiconductor circuit substrate 110 of the display device 10 shown in FIG. 6 may include a light transmitting portion that may transmit light therethrough or may be made of a material that may transmit light therethrough.

In concluding the detailed description, those skilled in the art will appreciate that many variations and modifications can be made to the embodiments without substantially departing from the principles and scope of the present disclosure. Therefore, the embodiments of the present disclosure are used in a generic and descriptive sense only and not for purposes of limitation.

What is claimed is:

1. A display device comprising:
a first substrate comprising pixel circuit units;
a plurality of light-emitting elements on the first substrate;
a partition wall filling gaps between the light-emitting elements and forming spaces in emission areas, on the light-emitting elements; and
wavelength conversion layers in the spaces.

2. The display device of claim 1, wherein the partition wall comprises an organic insulating material.

3. The display device of claim 1, further comprising:
a plurality of pixel electrodes on the pixel circuit units; and
connecting electrodes between the pixel electrodes and the light-emitting elements.

4. The display device of claim 1, further comprising:
a light-blocking member on the partition wall; and
color filters on the wavelength conversion layers.

5. The display device of claim 4, further comprising:
lenses on the light-emitting elements in the spaces to condense light.

6. The display device of claim 4, further comprising:
lenses on the color filters to condense light.

7. The display device of claim 1, further comprising:
first reflective layers on sides of each of the light-emitting elements; and
second reflective layers on sides of each of the wavelength conversion layers.

8. The display device of claim 7, wherein:
first surfaces of the second reflective layers are in contact with the sides of each of the wavelength conversion layers; and
second surfaces of the second reflective layers are in contact with the partition wall.

9. The display device of claim 8, wherein:
the wavelength conversion layers are longer than the light-emitting elements in a vertical direction perpendicular to a thickness direction; and
the display device further comprises third reflective layers at bottoms of parts of the wavelength conversion layers, the third reflective layer not overlapping with the light-emitting elements.

10. The display device of claim 3, further comprising:
a first insulating layer on parts of the first substrate where the pixel electrodes are not located; and
a second insulating layer on a top surface and sides of each of the light-emitting elements, sides of each of the connecting electrodes, and parts of the first insulating layer where the light-emitting elements are located,
wherein the second insulating layer includes openings on the top surfaces of the light-emitting elements.

11. The display device of claim 10, further comprising:
a common electrode on the second insulating layer and electrically connected to the light-emitting elements through the openings.

12. The display device of claim 1, wherein a width of the partition wall between the light-emitting elements is less than or equal to a width of the light-emitting elements.

13. The display device of claim 1, wherein:
the light-emitting elements comprise first, second, and third light-emitting elements configured to emit first light, second light, and third light, respectively; and
the wavelength conversion layers comprise a base resin and a scatterer configured to scatter light.

14. The display device of claim 1, wherein:
the light-emitting elements comprise first, second, and third light-emitting elements configured to emit first light, second light, and third light, respectively, and are located in first, second, and third emission areas, respectively; and
the wavelength conversion layers comprise a light-transmitting pattern in the first emission area and comprise a first base resin and a first scatterer configured to scatter light, a first wavelength conversion pattern in the second emission area and comprising a second base resin, a second scatterer configured to scatter light, and first wavelength conversion particles configured to convert the first light to the second light, and a second wavelength conversion pattern in the third emission area and comprising a third base resin, a third scatterer configured to scatter light, and second wavelength conversion particles configured to convert the first light to the third light.

15. The display device of claim 1, wherein each of the light-emitting elements comprises a first semiconductor layer, an active layer on the first semiconductor layer, and a second semiconductor layer on the active layer.

16. A method of fabricating a display device, comprising:
bonding a first substrate comprising a pixel electrode layer, and a second substrate comprising a light-emitting material layer;
fusion-bonding first connecting electrodes and second connecting electrodes and separating the second substrate from a light-emitting material layer;
forming light-emitting elements by etching the light-emitting material layer;
forming a partition wall and spaces for forming wavelength conversion layers, by applying an organic insulating material layer to cover the light-emitting elements and etching the organic insulating material layer on the light-emitting elements; and
forming the wavelength conversion layers in the spaces.

17. The method of claim 16, wherein the bonding the first and second substrates, comprises forming the first connecting electrodes and the second connecting electrodes on the first and second substrates, respectively, fusion-bonding the first connecting electrodes and the second connecting electrodes, and separating the second substrate from the light-emitting elements.

18. The method of claim 16, further comprising, after the forming the light-emitting elements:
forming an insulating layer on a top surface and sides of each of the light-emitting elements, on sides of each of connecting electrodes, and on parts of the first substrate where the light-emitting elements are not located;
forming openings exposing parts of the top surfaces of the light-emitting elements, by etching parts of the insulating layer on the top surfaces of the light-emitting elements; and
forming a common electrode on the openings and the insulating layer.

19. The method of claim 18, further comprising:
depositing reflective layers on the common electrode, removing parts of the reflective layers in first and second directions, with an etching material, by forming a large voltage difference in a third direction, and forming first reflective layers overlapping with sides of each of the light-emitting elements.

20. The method of claim 16, further comprising, before the forming the wavelength conversion layers;
depositing reflective layers on the partition wall and the spaces, removing parts of the reflective layers in first and second directions, with an etching material, by forming a large voltage difference in a third direction, and forming second reflective layers overlapping with sides of each of the spaces.

21. The method of claim 16, further comprising:
forming a light-blocking member on the partition wall; and
disposing color filters on the wavelength conversion layers.
